(19) United States
(12) Patent Application Publication
(10) Pub. No.: US 2026/0060094 A1
(43) Pub. Date: Feb. 26, 2026

(54) GLASS SUBSTRATE STRUCTURE

(71) Applicant: SAMSUNG ELECTRO-MECHANICS CO., LTD., Suwon-si (KR)

(72) Inventor: Jung Chul GONG, Suwon-si (KR)

(73) Assignee: SAMSUNG ELECTRO-MECHANICS CO., LTD., Suwon-si (KR)

(21) Appl. No.: 19/208,170

(22) Filed: May 14, 2025

(30) Foreign Application Priority Data
Aug. 23, 2024 (KR) 10-2024-0113308
Dec. 30, 2024 (KR) 10-2024-0200005

(51) Int. Cl. H01L 23/64; H01L 23/00; H01L 23/15; H01L 23/498; H01L 23/538

(52) U.S. Cl. CPC H01L 23/642; H01L 23/15; H01L 23/49822; H01L 23/49838; H01L 23/5383; H01L 23/5386; H01L 24/16; H01L 2224/16235; H01L 2924/1517

(57) ABSTRACT

A glass layer having a first surface and a second surface opposing each other in a first direction; a plurality of conductive through-vias penetrating at least a portion of the glass layer between the first surface and the second surface; and a capacitor member including a plurality of conductive electrodes each penetrating at least a portion of the glass layer between the first surface and the second surface. At least a portion of the plurality of conductive electrodes has regions overlapping each other in a second direction perpendicular to the first direction.

### CROSS-REFERENCE TO RELATED APPLICATIONS

This application claims benefit of priority to Korean Patent Application No. 10-2024-0200005 filed on Dec. 30, 2024 and Korean Patent Application No. 10-2024-0113308 filed on Aug. 23, 2024 in the Korean Intellectual Property Office, the disclosures of which are incorporated herein by reference in their entirety.

### BACKGROUND

### 1. Filled

The present disclosure relates to a glass substrate structure, more particularly, to a glass substrate structure including a glass layer on which a capacitor member is formed.

### 2. Description of Related Art

Recently, instead of a general organic substrate, a glass substrate having excellent high-frequency properties and advantageous for forming micro-patterns has been used. Also, in fields such as artificial intelligence (AI) and high-performance computing (HPC), signal integrity (SI) and power integrity (PI) performance have become important factors as high-speed operation and high integration density implemented.

### SUMMARY

An aspect of the present disclosure is to provide a glass substrate structure in which capacitors having various capacitances may be formed without a capacitor embedding process.

An aspect of the present disclosure is to provide a glass substrate structure which may improve signal integrity and power integrity performance.

According to an embodiment, a glass substrate structure includes a glass layer having a first surface and a second surface opposing each other in a first direction; a plurality of conductive through-vias penetrating at least a portion of the glass layer between the first surface and the second surface; and a capacitor member including a plurality of conductive electrodes each penetrating at least a portion of the glass layer between the first surface and the second surface. At least a portion of the plurality of conductive electrodes has regions overlapping each other in a second direction perpendicular to the first direction.

According to an embodiment, a glass substrate structure includes a glass layer; a plurality of first and second slits each penetrating the glass layer in a first direction, spaced apart from each other in a second direction perpendicular to the first direction, and each extending to a predetermined length in a third direction perpendicular to the first and second directions; and a metal material disposed in at least a portion of each of the plurality of first and second slits.

According to an embodiment, a glass substrate structure includes a glass layer having a first surface and a second surface opposing each other in a first direction; a capacitor member including first conductive electrodes and second conductive electrodes penetrating through the glass layer from the first surface to the second surface, and alternately disposed in a second direction crossing the first direction; a first conductive pattern disposed on the glass layer and connected to the first conductive electrodes; and a second conductive pattern disposed on the glass layer and connected to the second conductive electrodes.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating an example of an electronic device system;

FIG. 2 is a perspective diagram illustrating an example of an electronic device;

FIG. 3 is a cross-sectional diagram illustrating an example of a glass substrate structure;

FIG. 4 is a plan cross-sectional diagram taken along line A-A′ in FIG. 3;

FIG. 5 is a cross-sectional diagram illustrating a modified example of the glass substrate structure illustrated in FIG. 3;

FIG. 6 is a cross-sectional diagram illustrating a modified example of the glass substrate structure illustrated in FIG. 3;

FIG. 7 is a cross-sectional diagram illustrating another example of a glass substrate structure;

FIG. 8 is a plan cross-sectional diagram taken along line B-B′ in FIG. 7;

FIG. 9 is cross-sectional diagram illustrating a modified example of the glass substrate structure illustrated in FIG. 7;

FIG. 10 is a cross-sectional diagram illustrating a modified example of the glass substrate structure illustrated in FIG. 7;

FIG. 11 is a cross-sectional diagram illustrating another example of a glass substrate structure;

FIG. 12 is a plan cross-sectional diagram taken along line C-C′ in FIG. 11;

FIG. 13 is a cross-sectional diagram illustrating a modified example of the glass substrate structure illustrated in FIG. 11; and

FIG. 14 is a cross-sectional diagram illustrating a modified example of the glass substrate structure illustrated in FIG. 11.

### DETAILED DESCRIPTION

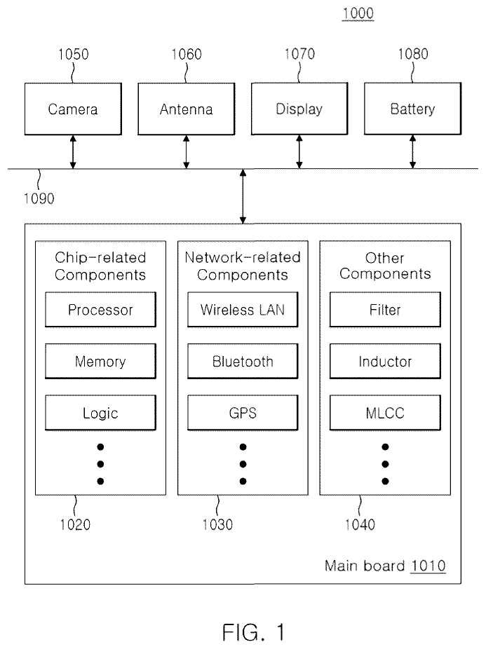

Hereinafter, embodiments of the present disclosure will be described as follows with reference to the attached drawings. Some elements may be exaggerated, omitted or briefly illustrated, and the sizes of the elements do not necessarily reflect the actual sizes of these elements FIG. 1 is a block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

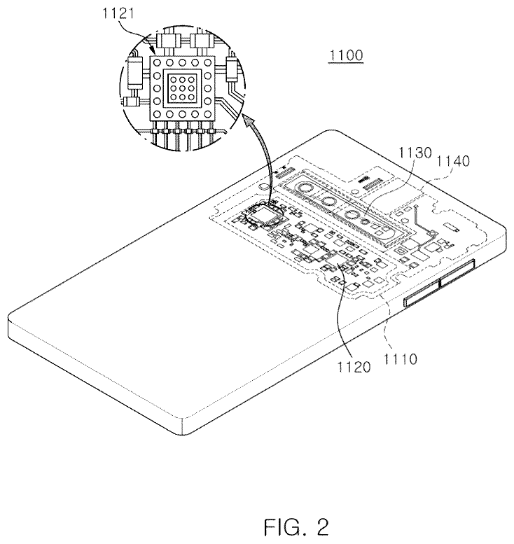

FIG. 2 is a perspective diagram illustrating an example of an electronic device.

Referring to FIG. 2, an electronic device may be a smartphone 1100. A motherboard 1110 may be accommodated in the smartphone 1100, and various components 1120 may be physically or electrically connected to the motherboard 1110. Also, other components which may or may not be physically or electrically connected to the motherboard 1110, such as a camera module 1130, may be accommodated in the body 1101. A portion of the components 1120 may be the chip related components, such as, for example, a component package 1121, but an example embodiment thereof is not limited thereto. The component package 1121 may have the form of a printed circuit board on which electronic components including active components and/or passive components are surface-mounted. Alternatively, the component package 1121 may be configured in the form of a printed circuit board in which active components and/or passive components are buried. The electronic device is not necessarily limited to the smartphone 1100, and may be other electronic devices as described above.

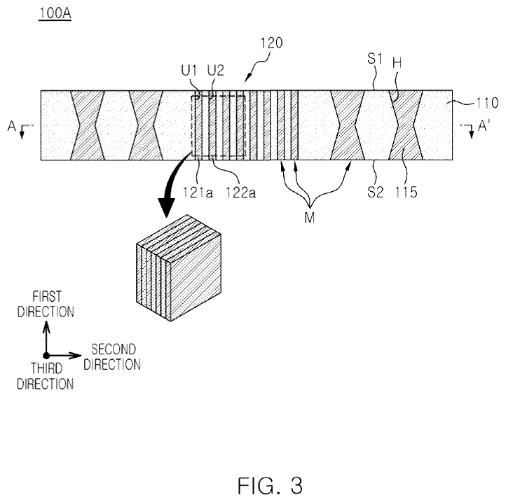

FIG. 3 is a cross-sectional diagram illustrating an example of a glass substrate structure.

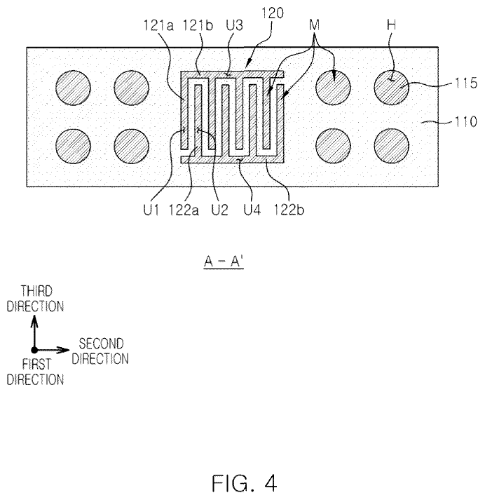

FIG. 4 is a plan cross-sectional diagram taken along line A-A′ in FIG. 3.

Referring to the drawings, a glass substrate structure 100A according to an example may include a glass layer 110 having a first surface S1 and a second surface S2 opposing each other in a first direction, a plurality of conductive through-vias 115 each penetrating at least a portion between the first surface S1 and the second surface S2 of the glass layer 110, and a capacitor member 120 including a plurality of conductive electrodes 121a and 122a each penetrating at least a portion between the first surface S1 and the second surface S2 of the glass layer 110. A minimum distance between the plurality of conductive electrodes 121a and 122a in the second direction may be smaller than a minimum distance between the plurality of conductive through-vias 115 in the second direction. At least a portion of the plurality of conductive electrodes 121a and 122a may have regions overlapping each other in the second direction. Accordingly, a capacitor capacitance may be formed.

For example, the plurality of conductive electrodes 121a and 122a may include a plurality of first conductive electrodes 121a and a plurality of second conductive electrodes 122a. The plurality of first conductive electrodes 121a may be electrically connected to each other and may be connected to each other in parallel. Accordingly, in the capacitor member 120, the plurality of electrodes may be used as electrodes having a negative or positive charge. The plurality of second conductive electrodes 122a may be electrically connected to each other and may be connected to each other in parallel. Accordingly, in the capacitor member 120, the plurality of electrodes may be used as electrodes having a negative or positive charge. In this case, the plurality of first conductive electrodes 121a and the plurality of second conductive electrodes 122a may be disposed alternately and spaced apart from each other in the second direction, and may have regions overlapping each other in the second direction. Also, at least a portion of the glass layer 110 may be disposed between the plurality of first conductive electrodes 121a and the plurality of second conductive electrodes 122a, respectively. The glass layer 110 may have a dielectric constant of, for example, about 5-10 depending on a material. Accordingly, capacitor capacitance may be easily formed, and desired capacitance may be easily implemented. For example, the capacitor member 120 of the desired capacitance may be directly formed on the glass layer 110. Accordingly, capacitors having various capacitances may be formed without a capacitor embedding process. Also, the glass substrate structure 100A may be applied to a package substrate structure or an assembly structure including an interposer to improve signal integrity and power integrity as described below.

Each of the plurality of first conductive electrodes 121a and the plurality of second conductive electrodes 122a may have a substantially panel shape. For example, each of the plurality of first conductive electrodes 121a may have a length in the first direction and a length in the third direction longer than a length in the second direction. Also, each of the plurality of second conductive electrodes 122a may have a length in the first direction and a length in the third direction longer than a length in the second direction. In this case, an area in which the plurality of first conductive electrodes 121a and the plurality of second conductive electrodes 122a overlap each other in the second direction may be optimized. Accordingly, capacitor capacitance required for the capacitor member 120 may be formed easily.

The capacitor member 120 may further include a first conductive connection portion 121b and a second conductive connection portion 122b each penetrating at least a portion between the first surface S1 and the second surface S2 of the glass layer 110. The first conductive connection portion 121b and the second conductive connection portion 122b may be spaced apart from each other in a third direction. The plurality of first conductive electrodes 121a and the plurality of second conductive electrodes 122a may be disposed between the first conductive connection portion 121b and the second conductive connection portion 122b. The plurality of first conductive electrodes 121a may be connected to the first conductive connection portion 121b in the third direction, respectively. The plurality of second conductive electrodes 122a may be connected to the second conductive connection portion 122b in the third direction, respectively. Accordingly, the plurality of first conductive electrodes 121a and the first conductive connection portion 122a may be easily used as electrodes having a positive charge or electrodes having a negative charge. Also, the plurality of second conductive electrodes 122a and the second conductive connection portion 122b may be easily used as electrodes having a positive or negative charge differently from the plurality of second conductive electrodes 122a and the second conductive connection portion 122b.

The first conductive connection portion 121b may have a substantially panel shape disposed almost perpendicularly to the plurality of first conductive electrodes 121a. For example, a length in the first direction and a length in the second direction of the first conductive connection portion 121b may be longer than a length in the third direction. Also, the second conductive connection portion 122b may have a substantially panel shape disposed almost perpendicularly to the plurality of second conductive electrodes 122a. For example, a length in the first direction and a length in the second direction of the second conductive connection portion 122b may be longer than a length in the third direction, respectively. In this case, the plurality of first conductive electrodes 121a and the plurality of second conductive electrodes 122a may be easily connected to the first conductive connection portion 121b and the second conductive connection portion 122b, respectively. Accordingly, the electrodes having a positive charge or electrodes having a negative charge required for the capacitor member 120 may be easily implemented.

If desired, various types of wiring directly connected to the plurality of conductive through-vias 115 and/or the capacitor member 120 may be formed on the first surface S1 and/or the second surface S2 of the glass layer 110. For example, a first conductive pattern connected to one or more of the plurality of first conductive electrodes 121a and the first conductive connection portion 121b, respectively, may be formed on the first surface S1 of the glass layer 110. Also, a second conductive pattern connected to one or more of the plurality of second conductive electrodes 122a and the second conductive connection portion 122b may be formed on the second surface S2 of the glass layer 110. Alternatively, each of the first and second conductive patterns may be formed on the first surface S1 of the glass layer 110, or each of the first and second conductive patterns may be formed on the second surface S2 of the glass layer 110.

Hereinafter, components of the glass substrate structure 100A according to an example will be described in greater detail with reference to the drawings.

The glass layer 110 may include glass, which is an amorphous solid. The glass may include, for example, pure silicon dioxide (about 100% SiO₂), soda-lime glass, borosilicate glass, alumino-silicate glass, or the like. However, an embodiment thereof is not limited thereto, and alternative glass materials, for example, fluorine glass, phosphate glass, chalcogen glass, or the like, may also be used as the material. Also, other additives may be further included to form glass having specific physical properties. These additives may include calcium carbonate (e.g., lime) and sodium carbonate (e.g., soda), and also magnesium, calcium, manganese, aluminum, lead, boron, iron, chromium, potassium, sulfur and antimony, and carbonates and/or oxides of these elements and other elements. The glass layer 110 may be distinct from an organic insulating material including glass fiber (glass cloth, glass fabric), for example, CCL (copper clad laminate), PPG (prepreg), or the like. The glass layer 110 may be, for example, in the form of a glass plate.

A plurality of conductive through-vias 115 may be disposed in a plurality of through-holes H each penetrating the glass layer 110 in the first direction. A plurality of conductive through-vias 115 may be a filled via filling the through-hole H with a conductive material, preferably a metal material M. The metal material M may include copper (Cu), aluminum (Al), silver (Ag), tin (Sn), gold (Au), nickel (Ni), lead (Pb), titanium (Ti), and/or an alloy thereof. For example, a region including each of the metal materials M of the plurality of conductive through-vias 115 may include a titanium layer and a copper layer formed by sputtering, that is, sputtered titanium and sputtered copper, as a seed layer, and may include electrolytic copper formed by electrolytic plating based on the titanium layer and the sputtered copper as a plating layer. If desired, chemical copper formed by electroless plating may be further included as a seed layer, and only chemical copper formed by electroless plating may be included as a seed layer. The plurality of conductive through-vias 115 may perform various functions depending on a design. For example, the plurality of conductive through-vias 115 may be signal transmission through-vias, power transmission through-vias, ground transmission through-vias, or the like. Each of the plurality of conductive through-vias 115 may have a substantially hourglass shape, but an embodiment thereof is not limited thereto, and each of the plurality of conductive through-vias 115 may also have a substantially cylindrical shape. A filler may be disposed in each of the plurality of conductive through-vias 115, and the filler may include an organic insulating material and/or an inorganic insulating material, but an embodiment thereof is not limited thereto. One surface and the other surface opposing each other in the first direction of the plurality of conductive through-vias 115 may be recessed inwardly of each of the first surface S1 and the second surface S2 of the glass layer 110, and each may have a step difference with respect to the first surface S1 and the second surface S2 of the glass layer 110.

The capacitor member 120 may include a plurality of first conductive electrodes 121a, a plurality of second conductive electrodes 122a, a first conductive connection portion 121b, and a second conductive connection portion 122b. The plurality of first conductive electrodes 121a may be disposed in a plurality of first slits U1 each penetrating the glass layer 110 in the first direction, spaced apart from each other in the second direction, and extending to a predetermined length in the third direction. The plurality of second conductive electrodes 122a may be disposed in a plurality of second slits U2 each penetrating the glass layer 110 in the first direction, spaced apart from each other in the second direction, and extending to a predetermined length in the third direction. The plurality of first slits U1 and the plurality of second slits U2 may be alternately spaced apart from each other in the second direction, and may have regions overlapping each other in the second direction. At least a portion of the plurality of first slits U1 and the plurality of second slits U2 may be filled with a metal material M. Accordingly, the plurality of first conductive electrodes 121a and the plurality of second conductive electrodes 122b may be formed. The first and second conductive connection portions 121b and 122b may be disposed in the third and fourth slits U3 and U4 penetrating the glass layer 110 in the first direction, spaced apart from each other in the third direction, and extending to a predetermined length in the second direction, respectively. The plurality of first slits U1 and the plurality of second slits U2 may be disposed between the third and fourth slits U3 and U4. Each of the plurality of first slits U1 may be connected to the third slit U3 in the third direction. Each of the plurality of second slits U2 may be connected to the fourth slit U4 in the third direction. At least a portion of the third and fourth slits U3 and U4 may also be filled with a metal material M. Accordingly, the first and second conductive connection portions 121b and 122b may be formed. Lengths in the first and third directions of the plurality of first slits U1 and the plurality of second slits U2 may be longer than lengths in the second direction. Lengths in the first and second directions of the third and fourth slits U3 and U4 may be longer than lengths in the third direction. The plurality of first slits U1 and the plurality of second slits U2 may have side surfaces substantially perpendicular to each other in a cross-section in the first and second directions, or may also have a substantially hourglass cross-sectional shape. The third and fourth slits U3 and U4 may have side surfaces substantially perpendicular in a cross-section in the first and third directions, or may also have a substantially hourglass cross-sectional shape. The regions including the metal material M of each of the plurality of first conductive electrodes 121a and the plurality of second conductive electrodes 122a and the first conductive connection portion 121b and the second conductive connection portion 122b may include a titanium layer and a copper layer formed by sputtering, that is, sputtered titanium and sputtered copper, as seed layers, and electrolytic copper formed by electrolytic plating based on the layer may be included as a plating layer. If desired, chemical copper formed by electroless plating may be further included as a seed layer, or only chemical copper formed by electroless plating may be included as a seed layer.

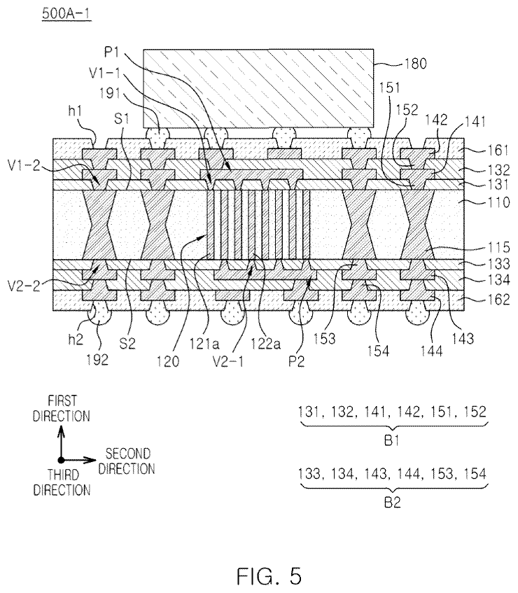

FIG. 5 is a cross-sectional diagram illustrating a modified example of the glass substrate structure illustrated in FIG. 3.

Referring to the drawings, a glass substrate structure 500A-1 according to the modified example may have a multilayer substrate structure including a glass substrate structure 100A according to the above-described example as a core layer. For example, the glass substrate structure 500A-1 according to the modified example may include a glass layer 110 having a plurality of conductive through-vias 115 and capacitor members 120 formed thereon, a first built-up layer B1 disposed on a first surface S1 of the glass layer 110, a second built-up layer B2 disposed on a second surface S2 of the glass layer 110, a first solder resist layer 161 disposed on the first built-up layer B1, and a second solder resist layer 162 disposed on the second built-up layer B2. For example, the glass substrate structure 500A-1 according to the modified example may have a package substrate structure. Accordingly, the structure may be easily applied to a product requiring a large-area substrate.

The first built-up layer B1 may include a plurality of first built-up insulating layers 131 and 132, a plurality of first built-up wiring layers 141 and 142 disposed on or in the plurality of first built-up insulating layers 131 and 132, and a plurality of first built-up via layers 151 and 152 disposed in the plurality of first built-up insulating layers 131 and 132, respectively. Accordingly, various wiring designs and electrical connection paths may be provided in the first built-up layer B1. Also, the second built-up layer B2 may include a plurality of second built-up insulating layer 133 and 134, a plurality of second built-up wiring layers 143 and 144 disposed on or in the second built-up insulating layer 133 and 134, respectively, and a plurality of second built-up via layers 153 and 154 disposed in the second built-up insulating layers 133 and 134, respectively. Accordingly, the second built-up layer B2 may also be provided with a variety of wiring designs and electrical connection paths. The number of layers of the plurality of first built-up insulating layers 131 and 132, the plurality of second built-up insulating layers 133 and 134, the plurality of first built-up wiring layers 141 and 142, the plurality of second built-up wiring layers 143 and 144, the plurality of first built-up via layers 151 and 152, and the plurality of second built-up via layers 153 and 153 may be greater than the example illustrated in the drawing, or may include only one layer.

One 151 of the plurality of first built-up via layers 151 and 152 may include at least a portion 141 of one 141 of the plurality of first built-up wiring layers 141 and 142, for example, a plurality of 1-1 built-up connection vias V1-1 electrically connecting the first conductive pattern P1 to a plurality of first conductive electrodes 121a and the first conductive connection portion 121b. Each of the plurality of 1-1 built-up connection vias V1-1 may be connected to one of the plurality of first conductive electrodes 121a and the first conductive connection portion 121b. Accordingly, a path electrically connected to the capacitor member 120 may be provided in the first built-up layer B1. Also, the plurality of second built-up via layers 153 and 154 may include at least a portion of the plurality of second built-up wiring layers 143 and 144, a plurality of 2-1 built-up connection vias V2-1 electrically connecting the second conductive pattern P2 to a plurality of second conductive electrodes 122a and the second conductive connection portion 122b. Each of the plurality of 2-1 built-up connection vias V2-1 may be connected to a plurality of second conductive electrodes 122a and the second conductive connection portion 122b. Accordingly, a path may be provided in the second built-up layer B2 electrically connected to the capacitor member 120.

The first and second conductive patterns P1 and P2 may be electrically connected to a power rail and ground, respectively, in the first and second built-up layers B1 and B2, but an embodiment thereof is not limited thereto, and both the first and second conductive patterns P1 and P2 may be electrically connected to signal lines in the first and second built-up layers B1 and B2, or may be electrically connected to signal lines and ground, respectively, in the first and second built-up layers B1 and B2. For example, the patterns may be connected in various manners depending on a function and role of the capacitor member 120. If desired, the first and second conductive patterns P1 and P2 may be disposed substantially at the same level, and may be included, for example, in one of the first built-up wiring layers 141 or in one of the second built-up wiring layers 143, respectively. In this case, the plurality of 1-1 built-up connection vias V1-1 and the plurality of 2-1 built-up connection vias V2-1 may also be disposed at substantially the same level, for example, the vias may be included in one of the first built-up via layers 151 or one of the second built-up via layers 153, respectively. For example, various designs may be configured.

One of the plurality of first built-up via layers 151 and 152 may further include a plurality of 1-2 built-up connection vias V1-2 directly connecting at least the other portion of one of the plurality of first built-up wiring layers 141 and 142 to one side of each of the plurality of conductive through-vias 115. Also, one 153 of the plurality of second built-up via layers 153 and 154 may further include a plurality of 2-2 built-up connections vias V2-2 directly connecting at least the other portion of one 143 of the plurality of second built-up wiring layers 143 and 144 to the other side of each of the plurality of conductive through-vias 115. Accordingly, an electrical connection path between the first built-up layer B1 and the second built-up layer B2 may be provided. Also, since the plurality of conductive through-vias 115 and the plurality of 1-2 and 2-2 built-up connection vias V1-2 and V2-2 are directly connected to each other, the electrical path may be reduced and the overall thickness of the substrate may be reduced.

The first solder resist layer 161 may have a plurality of first openings h1 each exposing one 142 of the plurality of first built-up wiring layers 141 and 142, for example, at least a portion of the first built-up wiring layer 142 disposed on the outermost side in the first direction. Also, the second solder resist layer 162 may have a plurality of second openings h2 each exposing one 144 of the plurality of second built-up wiring layers 143 and 144, for example, at least a portion of the second built-up wiring layer 144 disposed on the outermost side in the first direction. A plurality of first electrical connection metals 191 may be disposed on the plurality of first openings h1, respectively, and may be connected to at least a portion of the exposed first built-up wiring layer 142 disposed on the outermost side. A plurality of second electrical connection metals 192 may be disposed on the plurality of second openings h2, and may be connected to at least a portion of the exposed second built-up wiring layer 144 disposed on the outermost side. Each of the plurality of first electrical connection metals 181 may be connected to the electronic component 180. The electronic component 180 may be mounted on the first solder resist layer 161 through the plurality of first electrical connection metals 191. When the electronic component 180 is mounted as above, the glass substrate structure 500A-1 may be expanded to have, for example, a package structure.

The glass substrate structure 500A-1 may further include a frame in which a through-portion is formed, if desired. At least a portion of the glass layer 110 may be disposed in the through-portion. Each of the first and second built-up insulating layers 131 and 133 may cover at least a portion of the frame. At least one of the first and second built-up insulating layers 131 and 133 may fill at least a portion of the through-portion. However, an embodiment thereof is not limited thereto, and the through-portion may be filled with a separate filler. The frame may include various materials having excellent rigidity. Such a frame may be used as a jig during a process, and accordingly, the process may be performed at a panel level through the frame, and process warpage may be easily controlled. Also, the frame may remain in the final unit after singulation, and in this case, the frame may be more advantageous in controlling warpage of a final unit.

The glass substrate structure 500A-1 may be manufactured by the method as below. For example, first, a glass layer may be prepared using a glass plate. Thereafter, a plurality of through-holes, a plurality of first and second slits, and a third and fourth slits may be formed in the glass layer by laser processing, or the like. Thereafter, a plurality of through-holes, a plurality of first and second slits, and a portion of the third and fourth slits may be filled with a metal material by a process of forming a seed layer, a plating process, or the like, and a plurality of conductive through-vias, a plurality of first and second conductive electrodes, and a first and second conductive connection portions may be formed. For example, a capacitor member including the above components may be formed. Thereafter, a plurality of first and second built-up insulating layers, a plurality of first and second built-up wiring layers, and a plurality of first and second built-up via layers may be formed by a built-up process, or the like. For example, the first and second built-up layers may be formed. Thereafter, the first and second solder resist layers may be formed by a coating process or a lamination process. Thereafter, if desired, a plurality of first and second electrical connection metals may be formed, and an electronic component may be attached to the first solder resist layer using a plurality of first electrical connection metals and a reflow process may be performed, thereby mounting the electronic component. However, the method of manufacturing the glass substrate structure 500A-1 is not limited thereto.

Hereinafter, components of the glass substrate structure 500A-1 according to the modified example will be described in greater detail with reference to the drawings.

Each of a plurality of first and second built-up insulating layers 131, 132, 133, and 134 may be an insulating layer including an insulating material. The insulating material may include a thermosetting resin such as an epoxy resin, a thermoplastic resin such as a polyimide, or an inorganic filler, an organic filler, and/or glass fiber (glass cloth, glass fabric) together with these resins. For example, the insulating material may include insulating materials such as PPG (prepreg), Ajinomoto build-up film (ABF), photo imageable dielectric (PID), and resin clad copper (RCC), but an embodiment thereof is not limited thereto. The plurality of first built-up insulating layers 131 and 132 may include substantially the same insulating material, and accordingly, a boundary therebetween may be indistinct, or the boundary may be distinct. The plurality of second built-up insulating layers 133 and 134 may include substantially the same insulating material, and accordingly, a boundary therebetween may be indistinct, or the boundary may be distinct. The plurality of first built-up insulating layers 131 and 132 and the plurality of second built-up insulating layers 133 and 134 may have the same number of layers, but an embodiment thereof is not limited thereto, and the layers may have different numbers of layers.

The plurality of first and second built-up wiring layers 141, 142, 143, and 144 may be wiring layers including a metal. The metal may include copper (Cu), aluminum (Al), silver (Ag), tin (Sn), gold (Au), nickel (Ni), lead (Pb), titanium (Ti), and/or alloys thereof. For example, the plurality of first and second built-up wiring layers 141, 142, 143, and 144 may include chemical copper formed by electroless plating as a seed layer, and electrolytic copper formed by electrolytic plating based on the chemical copper may be included as a plating layer. Each of the plurality of first and second built-up wiring layers 141, 142, 143, and 144 may perform various functions depending on a design. For example, each of the plurality of first and second built-up wiring layers 141, 142, 143, and 144 may include a signal pattern, power pattern, and ground pattern. Each of these patterns may have various forms, such as a line, trace, plane, land, pad, and land.

The plurality of first and second built-up via layers 151, 152, 153, and 154 may be via layers including a metal. The metal may include copper (Cu), aluminum (Al), silver (Ag), tin (Sn), gold (Au), nickel (Ni), lead (Pb), titanium (Ti), and/or alloys thereof. For example, each of the plurality of first and second built-up via layers 151, 152, 153, and 154 may include chemical copper formed by electroless plating as a seed layer, and electrolytic copper formed by electrolytic plating based on the chemical copper may be included as a plating layer. Each of the plurality of first and second built-up via layers 151, 152, 153, and 154 may perform various functions depending on a design. For example, each of the plurality of first and second built-up via layers 151, 152, 153, and 154 may include a connection via for signal transmission, a connection via for power transmission, and a connection via for ground transmission. Each of these connection vias may be a built-up connection via or a conductive connection via. The plurality of first and second built-up via layers 151, 152, 153, and 154 may include a filled via (filled VIA) in which at least a portion of a via hole is filled with metal, or may also include a conformal via (conformal VIA) in which metal is disposed along a wall surface of the via hole. The plurality of first built-up via layers 151 and 152 and the plurality of second built-up via layers 153 and 154 may have substantially tapered shapes in opposite directions.

The first and second solder resist layers 161 and 162 may be outermost insulating layers or protective layers including an insulating material. The insulating material may include a thermosetting resin such as an epoxy resin, a thermoplastic resin such as a polyimide, or a resin together with an inorganic filler and/or an organic filler. For example, each of the first and second solder resist layers 161 and 162 may include Ajinomoto Build-up Film (ABF), solder resist (SR), or the like, but an embodiment thereof is not limited thereto. Each of the first and second solder resist layers 161 and 162 may be a liquid type or a film type, but an embodiment thereof is not limited thereto. Each of the first and second solder resist layers 161 and 162 may have a plurality of first and second openings h1 and h2 exposing at least a portion of a pattern on the outermost side. The patterns exposed to the plurality of first and second openings h1 and h2 may be SMD (solder mask defined) and/or NSMD (non-solder mask defined) types, but an embodiment thereof is not limited thereto.

The plurality of first and second electrical connection metals 191 and 192 may be formed of a low-melting point metal, for example, solder such as tin (Sn)-aluminum (Al)-copper (Cu), but an embodiment thereof is not limited thereto, and the material is not particularly limited thereto. Each of the plurality of first and second electrical connection metals 191 and 192 may include a solder ball or solder bump. The plurality of first and second electrical connection metals 191 and 192 may be formed in multilayers or a single layer, but an embodiment thereof is not limited thereto.

The electronic component 180 may include active components and/or passive components. The active component may include an integrated circuit die having hundreds to millions of components integrated into a single chip. The passive component may include various types of capacitors, inductors, or the like. The electronic component 180 may include a system on chip (SoC), but an embodiment thereof is not limited thereto. The electronic component 180 may be a plurality of electronic components if desired.

Other descriptions may be substantially the same as in the embodiment of the glass substrate structure 100A according to the example.

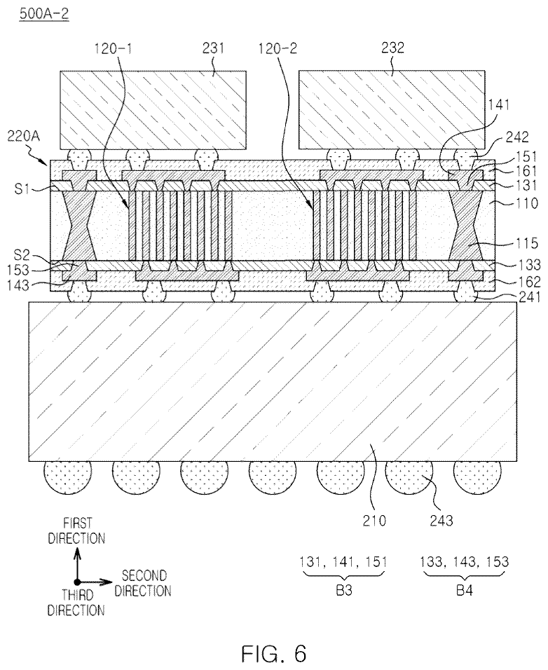

FIG. 6 is a cross-sectional diagram illustrating a modified example of the glass substrate structure illustrated in FIG. 3.

Referring to the drawings, the glass substrate structure 500A-2 according to the modified example may have an assembly structure of the package substrate 210 and the interposer 220A, and the interposer 220A may include the glass substrate structure 100A according to the above-described example. For example, the glass substrate structure 500A-2 according to the modified example may include the package substrate 210 and the interposer 220A mounted on the package substrate 210, and the interposer 220A may include a glass layer 110 on which a plurality of conductive through-vias 115 and a plurality of capacitor members 120-1 and 120-2 are formed. Each of the plurality of capacitor members 120-1 and 120-2 may include substantially the same component as the capacitor member 120 described above. The glass substrate structure 500A-2 according to the modified example may have an assembly structure as above, and may thus may be easily applied to various products requiring a package substrate and/or an interposer.

The interposer 220A may further include third and fourth built-up layers B3 and B4 disposed on a first surface S1 and a second surface S2 of the glass layer 110, respectively, and first and second solder resist layers 161 and 162 disposed on the third and fourth built-up layers B3 and B4, respectively. The third built-up layer B3 may include one or more first built-up insulating layers 131, one or more first built-up wiring layers 141, and one or more first built-up via layers 151. The fourth built-up layer B4 may include one or more second built-up wiring layers 133, one or more second built-up wiring layers 143, and one or more second built-up via layers 153. The first and second built-up wiring layers 141 and 143 may include a plurality of conductive patterns electrically connected to a plurality of capacitor members 120-1 and 120-2, respectively, and the first and second built-up via layers 151 and 153 may include a plurality of built-up connection vias providing such electrical connection paths, and also, the one or more first and second built-up via layers 151 and 153 may further include a plurality of built-up connection vias directly connected to a plurality of conductive through-vias 115, respectively. The specific descriptions thereof may be substantially the same as in the embodiment of the glass substrate structure 500A-1 described above.

The interposer 220A may be mounted on the package substrate 210 through a plurality of first electrical connection metals 241. For example, the plurality of first electrical connection metals 241 may electrically connect at least a portion of the second built-up wiring layer 133 of the fourth built-up layer B4 to at least a portion of a plurality of wiring layers of the package substrate 210. Also, a plurality of electronic components 231 and 232 may be mounted on the interposer 220A. The plurality of electronic components 231 and 232 may be mounted on the interposer 220A through a plurality of second electrical connection metals 242. For example, the plurality of second electrical connection metals 242 may electrically connect the plurality of electronic components 231 and 232 to at least a portion of a first built-up wiring layer 141 of the third built-up layer B3. When the plurality of electronic components 231 and 232 are mounted on the interposer 220A, the glass substrate structure 500A-2 may expand to have a package structure including, for example, an interposer. A plurality of third electrical connection metals 243 may be disposed on the opposite side of the package substrate 230 on which the interposer 220A is mounted with respect to the first direction. The plurality of third electrical connection metals 243 may be electrically connected to at least a portion of the plurality of wiring layers of the package substrate 210. The glass substrate structure 500A-2 of the assembly structure may be electrically connected to another substrate, such as a main board, or to another component, through the plurality of third electrical connection metals 243.

If desired, the third built-up layer B3 and/or the fourth built-up layer B4 may not be provided. For example, the plurality of first electrical connection metals 241 and/or the plurality of second electrical connection metals 242 may be directly connected to a plurality of conductive through-vias 115 and/or a plurality of capacitor members 120-1 and 120-2. Alternatively, various forms of wirings directly connected to the plurality of conductive through-vias 115 and/or a plurality of capacitor members 120-1 and 120-2 may be formed on the first surface S1 and/or the second surface S2 of the glass layer 110. For example, the structure of the interposer 220A may be varied.

If desired, the plurality of capacitor members 120-1 and 120-2 may be electrically connected only to a plurality of conductive patterns included in the third built-up layer B3, or only to a plurality of conductive patterns included in the fourth built-up layer B4. Also, the plurality of conductive patterns included in the third built-up layer B3 and/or the fourth built-up layer B4 may be electrically connected to a power rail and ground, or both may be electrically connected to a signal line, or both may be electrically connected to a signal line and ground. For example, as described above in relation to the glass substrate structure 500A-1, various designs may be configured, and various connection forms may be provided according to a functions and roles of the plurality of capacitor members 120-1 and 120-2.

The glass substrate structure 500A-2 may be manufactured by the method as below. For example, first, an interposer may be prepared. An interposer may be prepared by preparing a glass layer using a glass plate, forming a plurality of through-holes, a plurality of first and second slits, and a plurality of third and fourth slits in the glass layer using laser processing, forming a plurality of capacitor members by forming a plurality of conductive through-vias, a plurality of first and second conductive electrodes, and a plurality of first and second conductive connection portions by filling at least a portion of each of the plurality of through-holes, the plurality of first and second slits, and the third and fourth slits with a metal material through a process of forming a seed layer and a plating process, forming third and fourth built-up layers by forming one or more first and second built-up insulating layers, one or more first and second built-up wiring layers, and one or more first and second built-up via layers using a built-up process, and forming the first and second solder resist layers through a coating process or lamination process. If desired, a portion or the entirety of the built-up layer may not be provided, and necessary wiring may be formed directly in the glass layer. Thereafter, the interposer may be attached to the package substrate using a plurality of first electrical connection metals and may be mounted by performing a reflow process. Thereafter, if desired, the plurality of electronic components may be attacked to the interposer using a plurality of second electrical connection metals and a plurality of electronic components may be mounted by performing a reflow process. Also, a plurality of third electrical connection metals may be formed on the side opposite to the side of the package substrate on which the interposer is mounted with respect to the first direction. However, the method of manufacturing the glass substrate structure 500A-2 is not limited thereto.

Hereinafter, components of the glass substrate structure 500A-2 according to the modified example will be described in greater detail with reference to the drawings.

The package substrate 210 may include a multilayer substrate structure including a plurality of insulating layers, a plurality of wiring layers, and a plurality of via layers. The multilayer substrate structure may be configured as a core-type multilayer substrate structure. For example, the plurality of insulating layers may include a core insulating layer, and the core insulating layer may have a thickness greater than that of each of the other insulating layers. However, an embodiment thereof is not limited thereto, and the multilayer substrate structure may be configured as a coreless-type multilayer substrate structure. If desired, metal blocks or metal plates may be arranged in the plurality of insulating layers for heat dissipation or warpage control.

The plurality of insulating layers may be insulating layers each including an insulating material. The insulating material may include a thermosetting resin such as an epoxy resin, a thermoplastic resin such as polyimide, or inorganic filler, organic filler, and/or glass fiber (glass cloth, glass fabric) together with these resins. For example, the insulating material may include an insulating material of copper clad laminated (CCL), prepreg (PPG), Ajinomoto build-up film (ABF), photo imageable dielectric (PID), resin clad copper (RCC), or the like, but an embodiment thereof is not limited thereto. The plurality of insulating layers may include a core insulating layer, and the core insulating layer may have a thickness greater than that of each of the other insulating layers. However, an embodiment thereof is not limited thereto, and the plurality of insulating layers may include only built-up insulating layers.

The plurality of wiring layers may be wiring layers each including a metal. The metal may include copper (Cu), aluminum (Al), silver (Ag), tin (Sn), gold (Au), nickel (Ni), lead (Pb), titanium (Ti), and/or alloys thereof. For example, the plurality of wiring layers may include chemical copper formed by electroless plating as a seed layer, and electrolytic copper formed by electrolytic plating based on the chemical copper may be included as a plating layer. The plurality of wiring layers may perform various functions depending on a design. For example, the plurality of wiring layers may include a signal pattern, power pattern, ground pattern, or the like. Each of these patterns may have various forms such as a line, trace, plane, land, pad, and land.

The plurality of via layers may include a metal. The metal may include copper (Cu), aluminum (Al), silver (Ag), tin (Sn), gold (Au), nickel (Ni), lead (Pb), titanium (Ti), and/or alloys thereof. For example, the plurality of via layers may include chemical copper formed by electroless plating as a seed layer, and electrolytic copper formed by electrolytic plating based on the chemical copper may be included as a plating layer. The plurality of via layers may perform various functions depending on a design. For example, the plurality of via layers may include a connection via for signal transmission, a connection via for power transmission, a connection via for ground transmission, or the like. The connection vias may be built-up connection vias or conductive connection vias.

The plurality of first to third electrical connection metals 241, 242, and 243 may be formed of a low-melting point metal, such as solders such as tin (Sn)-aluminum (Al)-copper (Cu), but an embodiment thereof is not limited thereto, and the material is not particularly limited thereto. Each of the plurality of first to third electrical connection metals 241, 242, and 243 may include a solder ball or solder bump. Each of the plurality of first to third electrical connection metals 241, 242, and 243 may be formed as a multilayer or a single layer, but an embodiment thereof is not limited thereto.

Each of the plurality of electronic components 331 and 332 may include active components and/or passive components. The active components may include an integrated circuit die in which hundreds to millions of components are integrated into a single chip. The passive components may include various types of capacitors, inductors, and the like. Each of the plurality of electronic components 331 and 332 may include a system on chip (SoC), but an embodiment thereof is not limited thereto.

Other descriptions may be substantially the same as in the embodiment of the glass substrate structure 100A according to the example and the glass substrate structure 500A-1 according to the modified example.

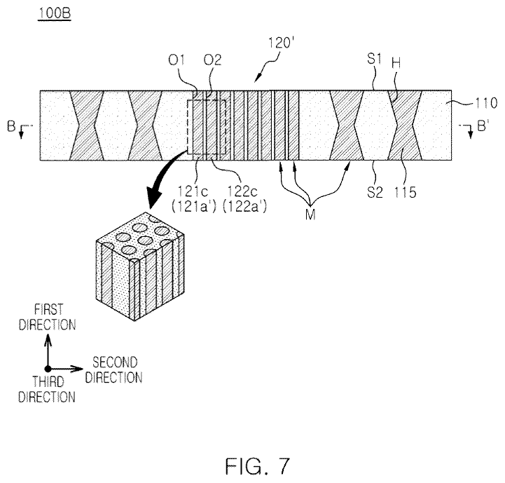

FIG. 7 is a cross-sectional diagram illustrating another example of a glass substrate structure.

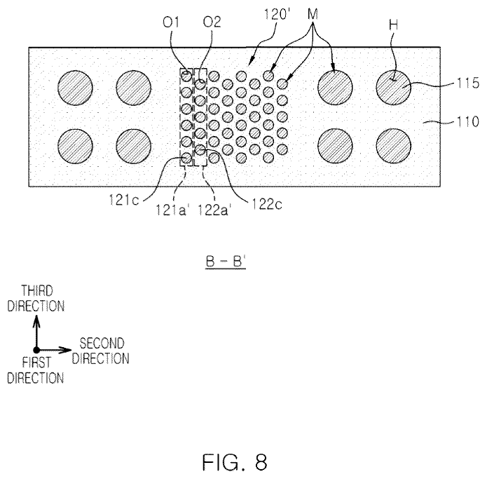

FIG. 8 is a plan cross-sectional diagram taken along line B-B′ in FIG. 7.

Referring to the drawings, a glass substrate structure 100B according to another example may include a plurality of first conductive vias 121c in which a plurality of first conductive electrodes 121a′ of a capacitor member 120′ are disposed and spaced apart from each other in a third direction in the glass substrate structure 100A according to the above-described example. Also, a plurality of second conductive electrodes 122a′ of a capacitor member 120′ may include a plurality of second conductive vias 122c in which a plurality of second conductive electrodes 122a′ are disposed and spaced apart from each other in the third direction. Also, the first and second conductive connection portions 121b and 122b described above may not be provided. A plurality of first conductive vias 121c of each of the plurality of first conductive electrodes 121a′ and a plurality of second conductive vias 122c of each of the plurality of second conductive electrodes 122a′ may be spaced apart from each other in a second direction and disposed alternately, and may overlap each other in the second direction. Accordingly, capacitor capacitance may be formed.

For example, the plurality of first conductive vias 121c of each of the plurality of first conductive electrodes 121a′ may be electrically connected to each other when the glass substrate structure 100B is applied to an assembly structure including a package substrate structure or an interposer, as described below, and may also be connected to each other in parallel. Accordingly, the capacitor member 120′ may be used as an electrode having a positive or negative charge. Also, the plurality of second conductive electrodes 122a′ and the plurality of second conductive vias 122c may be electrically connected to each other when the glass substrate structure 100B is applied to a package substrate structure or an assembly structure including an interposer, as described below, and may also be connected to each other in parallel. Accordingly, the capacitor member 120′ may be used as an electrode having a negative or positive charge in the opposite direction. In this case, the plurality of first conductive electrodes 121a′ and the plurality of second conductive electrodes 122a′ may be spaced apart from each other in the second direction and may be disposed alternately, and may also have regions overlapping each other in the second direction. Also, at least a portion of a glass layer 110 having a dielectric constant of, for example, about 5-10 may be disposed therebetween depending on the material. Accordingly, a capacitor capacitance may be easily formed, and desired capacitance may be easily implemented. For example, the capacitor member 120′ of a desired capacitance may be formed directly on the glass layer 110. Accordingly, capacitors of various capacitances may be easily formed without a capacitor embedding process. Also, as described below, by applying the glass substrate structure 100B to an assembly including a package substrate or an interposer, signal integrity and power integrity may improve.

Each of a plurality of first conductive electrodes 121a′ of each of the plurality of first conductive vias 121c may have a substantially circular or elliptical shape in a cross-section in the second and third directions. Also, each of a plurality of second conductive electrodes 122a′ of each of the plurality of second conductive vias 122c may have a substantially circular or elliptical shape in the cross-section in the second and third directions. For example, the plurality of conductive through-vias 115 may have substantially the same shape in the cross-section in the second and third directions and only a size may be different. In this case, the process of manufacturing the capacitor member 120′ may be simplified.

The plurality of first conductive vias 121c of each of the plurality of first conductive electrodes 121a′ and the plurality of second conductive vias 122c of each of the plurality of second conductive electrodes 122a′ may be arranged in a zigzag pattern. Through this shape and arrangement, a larger number of conductive vias may be formed in a limited space, and the overlap region may be optimized. If desired, the plurality of first conductive vias 121c of each of the plurality of first conductive electrodes 121a′ and the plurality of second conductive vias 122c of each of the plurality of second conductive electrodes 122a′ may be aligned with each other in rows. For example, the plurality of first conductive vias 121c of each of the plurality of first conductive electrodes 121a′ and the plurality of second conductive vias 122c of each of the plurality of second conductive electrodes 122a′ may be arranged in positions corresponding to each other in the second direction. In this case, the overlapping region may be maximized.

If desired, various forms of wirings directly connected to the plurality of conductive through-vias 115 and/or the capacitor member 120′ may be formed on the first surface S1 and/or the second surface S2 of the glass layer 110. For example, a first conductive pattern connected to each of the plurality of first conductive vias 121c of each of the plurality of first conductive electrodes 121a′ may be formed on the first surface S1 of the glass layer 110. In this case, the plurality of first conductive electrodes 121a′ and the plurality of first conductive vias 121c may be electrically connected to each other. Also, a second conductive pattern connected to the plurality of second conductive vias 122c of each of the plurality of second conductive electrodes 122a′ may be formed on the second surface S2 of the glass layer 110. In this case, the plurality of second conductive electrodes 122a′ and the plurality of second conductive vias 122c may be electrically connected to each other. Alternatively, the first and second conductive patterns may be formed on the first surface S1 of the glass layer 110. Alternatively, the first and second conductive patterns may be formed on the second surface S2 of the glass layer 110.

Hereinafter, components of the glass substrate structure 100B according to an example will be described in greater detail with reference to the drawings.

The capacitor member 120′ may include a plurality of first conductive electrodes 121a′ and a plurality of second conductive electrodes 122a'. Each of the plurality of first conductive electrodes 121a′ may include a plurality of first conductive vias 121c. Each of the plurality of second conductive electrodes 122a′ may include a plurality of second conductive vias 122c. The plurality of first conductive vias 121c of each of the plurality of first conductive electrodes 121a′ may penetrate the glass layer 110 in the first direction and may be disposed in a plurality of first holes O1 spaced apart from each other in the third direction. The plurality of second conductive vias 122c of each of the plurality of second conductive electrodes 122a′ may penetrate the glass layer 110 in the first direction and may be disposed in a plurality of second holes O2 spaced apart from each other in the third direction. The plurality of first hole portions each including the plurality of first holes O1 and the plurality of second hole portions each including the plurality of second holes O2 may be disposed alternately and spaced apart from each other in the second direction and may have regions overlapping each other in the second direction. At least a portion of each of the plurality of first holes O1 and each of the plurality of second holes O2 may be filled with a metal material M. Accordingly, the plurality of first conductive electrodes 121a′ each including the plurality of first conductive vias 121c and the plurality of second conductive electrodes 122a′ each including the plurality of second conductive vias 122c may be formed. The plurality of first holes O1 of each of the plurality of first hole portions and the plurality of the second holes O2 of each of the plurality of second hole portions may have substantially a circular or elliptical shape in the cross-section in the second and third directions, respectively. A region including a metal material M of the plurality of first conductive vias 121c of each of the plurality of first conductive electrodes 121a′ and the plurality of second conductive vias 122c of each of the plurality of second conductive electrodes 122a′ may include a titanium layer and a copper layer formed by sputtering, that is, sputtered titanium and sputtered copper, as seed layers, and electrolytic copper formed based on the layer by electroplating may be included as a plating layer. If desired, the chemical copper formed by electroless plating may be further included as a seed layer, or only the chemical copper formed by electroless plating may be included as a seed layer.

Other descriptions may be substantially the same as in the embodiment of the glass substrate structure 100A according to the example.

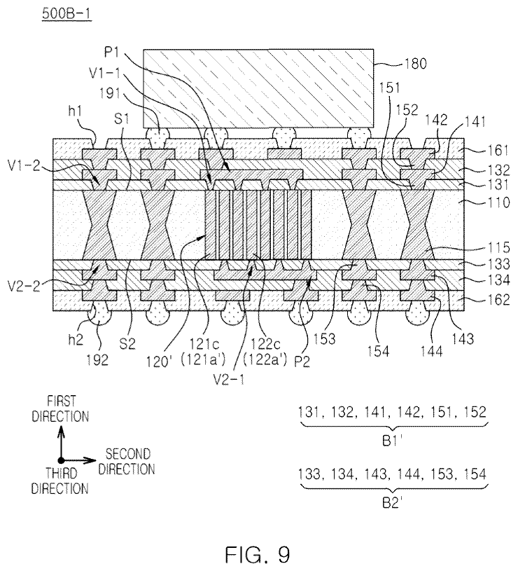

FIG. 9 is cross-sectional diagram illustrating a modified example of the glass substrate structure illustrated in FIG. 7.

Referring to the drawings, the glass substrate structure 500B-1 according to the modified example may have a multilayer substrate structure including the glass substrate structure 100B according to the other example described above as a core layer. For example, the glass substrate structure 500B-1 according to the modified example may include a glass layer 110 having a plurality of conductive through-vias 115 and capacitor members 120′ formed thereon, a first built-up layer B1′ disposed on a first surface S1 of the glass layer 110, a second built-up layer B2′ disposed on a second surface S2 of the glass layer 110, a first solder resist layer 161 disposed on the first built-up layer B1′, and a second solder resist layer 162 disposed on the second built-up layer B2'. For example, the glass substrate structure 500B-1 according to the modified example may have a package substrate structure. Accordingly, the structure may be easily applied to a product requiring a large-area substrate.

The first built-up layer B1′ may include a plurality of first built-up insulating layers 131 and 132, a plurality of first built-up wiring layers 141 and 142 disposed on or in the first built-up insulating layers 131 and 132, respectively, and a plurality of first built-up via layers 151 and 152 disposed in the first built-up insulating layers 131 and 132, respectively. Accordingly, various wiring designs and electrical connection paths may be provided in the first built-up layer B1′. Also, the second built-up layer B2′ may include a plurality of second built-up insulating layer 133 and 134, a plurality of first built-up wiring layers 143 and 144 disposed on or in the second built-up insulating layer 133 and 134, respectively, and a plurality of first built-up via layers 153 and 154 disposed in the first built-up insulating layers 133 and 134, respectively. Accordingly, the second built-up layer B2′ may also be provided with a variety of wiring designs and electrical connection paths. The number of layers of the plurality of first built-up insulating layers 131 and 132, the plurality of second built-up insulating layers 133 and 134, the plurality of first built-up wiring layers 141 and 142, the plurality of second built-up wiring layers 143 and 144, the plurality of first built-up via layers 151 and 152 and the plurality of second built-up via layers 153 and 153 may be greater than the illustrated example, but an embodiment thereof is not limited thereto, and the number of layer may be one.

One 151 of the plurality of first built-up via layers 151 and 152 may include plurality of 1-1 built-up connection vias V1-1 connecting at least a portion of one 141 of the plurality of first built-up wiring layers 141 and 142, for example, a first conductive pattern P1, to each of the plurality of first conductive vias 121c of each of the plurality of first conductive electrodes 121a′. The plurality of 1-1 built-up connection vias V1-1 may be connected to a plurality of first conductive vias 121c of each of the plurality of first conductive electrodes 121a′ in a one-to-one relationship. Accordingly, the plurality of first conductive vias 121c of each of the plurality of first conductive electrodes 121a′ may be electrically connected to each other. Also, a path may be provided in the first built-up layer B1′ electrically connected to the capacitor member 120′. Also, a plurality of second built-up via layers 153, 154, and 153 may include at least a portion of a plurality of second built-up wiring layers 143, 144, and 143, for example, a plurality of 2-1 built-up connections via V2-1 connecting a second conductive pattern P2 to the plurality of second conductive vias 122c of each of the plurality of second conductive electrodes 122a′. The plurality of 2-1 built-up connections via V2-1 may be connected to the plurality of second conductive vias 122c of each of the plurality of second conductive electrodes 122a′ in a one-to-one relationship. Accordingly, the plurality of second conductive electrodes 122a′ and the plurality of second conductive vias 122c may be electrically connected to each other. Also, a path electrically connected to the capacitor member 120′ may be provided in the second built-up layer B2′.

The first and second conductive patterns P1 and P2 may be electrically connected to a power rail and ground, respectively, in the first and second built-up layers B1′ and B2′, but an embodiment thereof is not limited thereto, and both the patterns may be electrically connected to a signal line in the first and second built-up layers B1′ and B2′, or may be electrically connected to a signal line and ground, respectively, in the first and second built-up layers B1′ and B2′. For example, the patterns may be connected in various forms depending on a function and role of the capacitor member 120′. If desired, each of the first and second conductive patterns P1 and P2 may be disposed substantially at the same level, and may be included, for example, in one of the first built-up wiring layer 141 or in one of the second built-up wiring layer 143. In this case, the plurality of 1-1 built-up connection vias V1-1 and a plurality of 2-1 built-up connection vias V2-1 may also be disposed at substantially the same level, for example, each of the patterns may be included in one of the first built-up via layers 151 or one of the second built-up via layers 153, respectively. For example, various designs may be configured.

One of the plurality of first built-up via layers 151 and 152 may further include a plurality of 1-2 built-up connection vias V1-2 directly connecting at least the other portion of one 141 of the plurality of first built-up wiring layers 141 and 142 to one side of each of the plurality of conductive through-vias 115. Also, one 153 of the plurality of second built-up via layers 153 and 154 may further include a plurality of 2-2 built-up connections vias V2-2 directly connecting at least the other portion of one 143 of the plurality of second built-up wiring layers 143 and 144 to the other side of each of the plurality of conductive through-vias 115. Accordingly, an electrical connection path between the first built-up layer B1′ and the second built-up layer B2′ may be provided. Also, since the plurality of conductive through-vias 115 and the plurality of 1-2 and 2-2 built-up connections via V1-2 and V2-2 are directly connected to each other, an electrical path may be reduced and an overall thickness of the substrate may be reduced.

Other descriptions may be substantially the same as in the example of the glass substrate structure 100A according to an embodiment and the glass substrate structure 500A-1 according to the modified example thereof, and the glass substrate structure 100B according to another embodiment.

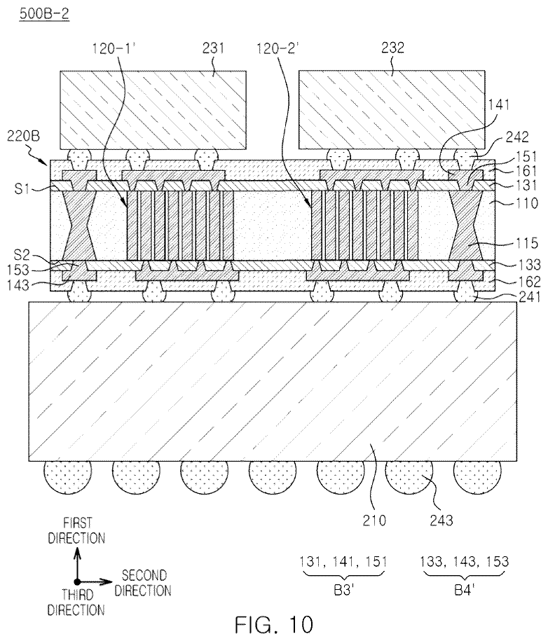

FIG. 10 is a cross-sectional diagram illustrating a modified example of the glass substrate structure illustrated in FIG. 7.

Referring to the drawings, a glass substrate structure 500B-2 according to the modified example may have an assembly structure of a package substrate 210 and an interposer 220B, and the interposer 220B may include the glass substrate structure 100B according to the other example described above. For example, the glass substrate structure 500B-2 according to the modified example may include the package substrate 210 and the interposer 220B mounted on the package substrate 210, and the interposer 220B may include a glass layer 110 on which a plurality of conductive through-vias 115 and a plurality of capacitor members 120-1′ and 120-2′ are formed. Each of the plurality of capacitor members 120-1′ and 120-2′ may include substantially the same component as the capacitor member 120′ described above. The glass substrate structure 500B-2 according to the modified example may have an assembly structure as described above, and thus the structure may be easily applied to various products requiring a package substrate and/or an interposer.

The interposer 220B may further include third and fourth built-up layers B3′ and B4′ disposed on the first surface S1 and second surface S2 of the glass layer 110, respectively, and first and second solder resist layers 161 and 162 disposed on the third and fourth built-up layers B3′ and B4′, respectively. The third built-up layer B3′ may include one or more first built-up insulating layers 131, one or more first built-up wiring layers 141, and one or more first built-up via layers 151. The fourth built-up layer B4′ may include one or more second built-up wiring layers 133, one or more second built-up wiring layers 143, and one or more second built-up via layers 153. The first and second built-up wiring layers 141 and 143 may include a plurality of conductive patterns electrically connected to a plurality of capacitor members 120-1′ and 120-2', respectively, and the first and second built-up via layers 151 and 153 may include a plurality of built-up connection vias providing such electrical connection paths, and also, one or more first and second built-up via layers 151 and 153 may further include a plurality of built-up connection vias directly connected to the plurality of conductive through-vias 115, respectively. The specific descriptions thereof may be substantially the same as in the embodiment of the glass substrate structure 500B-1 described above.

If desired, the third built-up layer B3′ and/or the fourth built-up layer B4′ may not be provided. For example, a plurality of first electrical connection metals 241 and/or a plurality of second electrical connection metals 242 may be directly connected to a plurality of conductive through-vias 115 and/or a plurality of capacitor members 120-1′ and 120-2′. Alternatively, various types of wirings directly connected to the plurality of conductive through-vias 115 and/or the plurality of capacitor members 120-1′ and 120-2′ may be formed on the first surface S1 and/or the second surface S2 of the glass layer 110. For example, the structure of the interposer 220B may be varied.

If desired, the plurality of capacitor members 120-1′ and 120-2′ may be electrically connected only to the plurality of conductive patterns included in the third built-up layer B3′, or only to the plurality of conductive patterns included in the fourth built-up layer B4′. Also, a plurality of conductive patterns included in the third built-up layer B3′ and/or the fourth built-up layer B4′ may be electrically connected to a power rail and ground, or both may be electrically connected to a signal line, or both may be electrically connected to a signal line and ground. For example, as described above in relation to the glass substrate structure 500B-1, various designs may be configured, and various connection forms may be implemented depending on functions and roles of the plurality of capacitor members 120-1′ and 120-2′.

Other descriptions may be substantially the same as in the embodiment of the glass substrate structure 100A according to an example, the glass substrate structures 500A-1 and 500A-2 according to the modified example thereof, the glass substrate structure 100B according to another example and the glass substrate structure 500B-1 according to the modified example thereof.

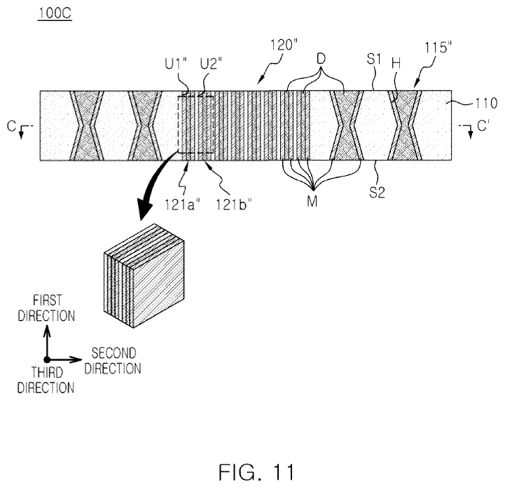

FIG. 11 is a cross-sectional diagram illustrating another example of a glass substrate structure.

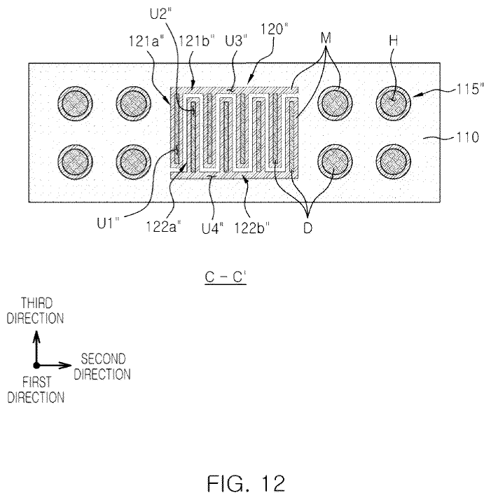

FIG. 12 is a plan cross-sectional diagram taken along line C-C′ in FIG. 11.

Referring to the drawings, in a glass substrate structure 100C according to another example, a dielectric material D may be disposed in each of first and second conductive electrodes 121a″ and 122a″ of a capacitor member 120″ in the glass substrate structure 100A according to the above-described example. The metal material M of each of the plurality of first and second conductive electrodes 121a″ and 122a′ may surround the dielectric material D in the cross-section in the second and third directions. For example, the glass layer 110, the metal material M, the dielectric material D and the metal material M may be disposed alternately in order in the second direction and may overlap each other. When the dielectric material D is disposed in each of the plurality of first and second conductive electrodes 121a″ and 122a″, capacitance of the capacitor member 120″ may be controlled using a dielectric constant of the dielectric material D. If desired, the plurality of dielectric materials D may be disposed in the conductive through-via 115″. In this case, when filling each of the plurality of first and second conductive electrodes 121a″ and 122a″ with the dielectric material D, the plurality of dielectric materials D may also be filled in each of the plurality of conductive through-vias 115″, and accordingly, the process may be simplified.

For example, the plurality of conductive electrodes 121a″ and 122a″ may include a plurality of first conductive electrodes 121a″ and a plurality of second conductive electrodes 122a″. The plurality of first conductive electrodes 121a″ may be electrically connected to each other and may be connected to each other in parallel. Accordingly, a plurality of electrodes having a positive or negative charge may be used in the capacitor member 120″. The plurality of second conductive electrodes 122a″ may be electrically connected to each other and may be connected to each other in parallel. Accordingly, the capacitor member 120″ may be used as an electrode having a positive or negative charge in the opposite direction. In this case, the plurality of first conductive electrodes 121a″ and the plurality of second conductive electrodes 122a″ may be alternately disposed and may be spaced apart from each other in the second direction, and may also have regions overlapping each other in the second direction. Accordingly, the glass layer 110, the metal material M, the dielectric material D, and the metal material M may be alternately disposed in order in the second direction and may overlap each other. The glass layer 110 may have a dielectric constant of, for example, 5-10 depending on the material, and the dielectric material D may have a more diverse dielectric constant depending on the material. Accordingly, the capacitor capacitance may be easily formed, and the desired capacitance may be easily implemented. For example, the capacitor member 120″ having a desired capacitance may be directly formed on the glass layer 110. Accordingly, capacitors having various capacitances may be formed without a capacitor embedding process. Also, as described later, the glass substrate structure 100C may be applied to a package substrate structure or an assembly structure including an interposer, thereby improving signal integrity and power integrity.

Each of the plurality of first conductive electrodes 121a″ and the plurality of second conductive electrodes 122a″ may have a substantially panel shape. For example, a length in the first direction and a length in the third direction of each of the plurality of first conductive electrodes 121a″ may be longer than a length in the second direction. Also, a length in the first direction and a length in the third direction of each of the plurality of second conductive electrodes 122a″ may be longer than a length in the second direction. In this case, an area in which the plurality of first conductive electrodes 121a″ and the plurality of second conductive electrodes 122a″ overlap each other in the second direction may be optimized. Accordingly, the capacitor capacitance required for the capacitor member 120″ may be formed easily.

The capacitor member 120″ may further include a first conductive connection portion 121b″ and a second conductive connection portion 122b″ each penetrating at least a portion between the first surface S1 and the second surface S2 of the glass layer 110. The first conductive connection portion 121b″ and the second conductive connection portion 122b″ may be spaced apart from each other in the third direction. The plurality of first conductive electrodes 121a″ and the plurality of second conductive electrodes 122a″ may be disposed between the first conductive connection portion 121b″ and the second conductive connection portion 122b″. Each of the plurality of first conductive electrodes 121a″ may be connected to the first conductive connection portion 121b″ in the third direction, respectively. Each of the plurality of second conductive electrodes 122a″ may be connected to the second conductive connection portion 122b″ in the third direction, respectively. Accordingly, the plurality of first conductive electrodes 121a″ and the first conductive connection portion 122a″ may be easily used as electrodes having a positive charge or electrodes having a negative charge. Also, the plurality of second conductive electrodes 122a″ and the second conductive connection portion 122b″ may be easily used as electrodes having a positive charge or electrodes having a negative charge, respectively.

The first conductive connection portion 121b″ may have a substantially panel shape disposed almost perpendicular to the plurality of first conductive electrodes 121a″. For example, a length in the first direction and a length in the second direction of the first conductive connection portion 121b″ may be longer than a length in the third direction. Also, the second conductive connection portion 122b″ may have a substantially panel shape disposed almost perpendicular to the plurality of second conductive electrodes 122a″. For example, a length in the first direction and a length in the second direction of the second conductive connection portion 122b″ may be longer than a length in the third direction. In this case, the plurality of first conductive electrodes 121a″ and the plurality of second conductive electrodes 122a″ may be easily connected to the first conductive connection portion 121b″ and the second conductive connection portion 122b″, respectively. Accordingly, the electrode having a positive charge or the electrode having a negative charge required for the capacitor member 120″ may be easily implemented.

If desired, various forms of wirings may be formed directly connected to the plurality of conductive through-vias 115″ and/or the capacitor member 120″ on the first surface S1 and/or the second surface S2 of the glass layer 110. For example, a plurality of first conductive pads each covering one side of the conductive through-via 115″, a plurality of first conductive cover electrodes each covering one side of the first conductive electrodes 121a″ and the first conductive connection portion 121b″, and a plurality of second conductive cover electrodes each covering one side of the second conductive electrodes 122a″ and the second conductive connection portion 122b″ may be disposed on the first surface S1 of the glass layer 110. Also, a plurality of second conductive pads each covering the other side of the conductive through-via 115″, a plurality of third conductive cover electrodes each covering the other side of the first conductive electrodes 121a″ and the first conductive connection portion 121b″, and a plurality of second conductive cover electrodes each covering the other side of the second conductive electrodes 122a″ and the second conductive connection portion 122b″ may be disposed on the second surface S2 of the glass layer 110. For example, the dielectric material D may not be exposed to one side and the other side through a plurality of first and second conductive pads and the first to fourth conductive cover electrodes disposed on the first surface S1 and the second surface S2 of the glass layer 110. The plurality of first and second conductive pads and the first to fourth conductive cover electrode may include a metal such as copper (Cu), aluminum (Al), silver (Ag), tin (Sn), gold (Au), nickel (Ni), lead (Pb), titanium (Ti), and/or alloys thereof, and may be formed by an additional seed layer formation process and a plating process.

Hereinafter, components of a glass substrate structure 100C according to an example will be described in greater detail with reference to the drawings.

The capacitor member 120″ may include a plurality of first conductive electrodes 121a″, a plurality of second conductive electrodes 122a″, a first conductive connection portion 121b″, and a second conductive connection portion 122b″. The plurality of first conductive electrodes 121a″ may be disposed in a plurality of first slits U1″ each penetrating the glass layer 110 in the first direction, spaced apart from each other in the second direction, and extending to a predetermined length in the third direction. The plurality of second conductive electrodes 122a″ may be disposed in a plurality of second slits U2″ each penetrating the glass layer 110 in the first direction, spaced apart from each other in the second direction, and extending to a predetermined length in the third direction. The plurality of first slits U1″ and the plurality of second slit U2″ may be disposed alternately and spaced apart from each other in the second direction, and may have regions overlapping each other in the second direction. Each of the plurality of first slits U1″ and the plurality of second slits U2″ may have at least a portion filled with a metal material M, and at least the other portion may be filled with a dielectric material D. The dielectric material D may include various materials such as a polymer material, inorganic material, low-κ material, hybrid material, and special material. For example, the metal material M may be substantially conformally disposed on wall surfaces of each of the plurality of first slits U1″ and the plurality of second slit U2″, and the dielectric material D may fill at least a portion between the metal materials M of the plurality of first slits U1″ and the plurality of second slit U2″. Accordingly, the plurality of first conductive electrodes 121a″ and the plurality of second conductive electrodes 122b″ may be formed. The first and second conductive connection portions 121b″ and 122b″ may be disposed in third and fourth slits U3″ and U4″ penetrating the glass layer 110 in the first direction, spaced apart from each other in the third direction, and extending to a predetermined length in the second direction. The plurality of first slits U1″ and the plurality of second slit U2″ may be disposed between the third and fourth slits U3″ and U4″. The plurality of first slits U1″ may be connected to the third slit U3″ in the third direction, respectively, and the plurality of second slits U2″ may be connected to the fourth slit U4″ in the third direction, respectively. The third and fourth slits U3″ and U4″ may also be filled with at least a portion of the metal material M. Preferably, the third and fourth slits U3″ and U4″ may be substantially completely filled with the metal material M. For example, the third and fourth slits U3″ and U4″ may not be filled with the dielectric material D. Accordingly, the first and second conductive connection portions 121b″ and 122b″ may be formed. The lengths in the first and third directions of the plurality of first slits U1″ and the plurality of second slit U2″ may be longer than lengths in the second direction. The lengths in the first and second directions of the third and fourth slits U3″ and U4″ may be longer than lengths in the third direction. The lengths in the second direction of the plurality of first slits U1″ and the plurality of second slit U2″ may be longer than the lengths in the third direction of the third and fourth slits U3″ and U4″. Side surfaces of the plurality of first slits U1″ and the plurality of second slit U2″ may be substantially perpendicular to each other in a cross-section in the first and second directions, but an embodiment thereof is not limited thereto, and the side surfaces may have a substantially hourglass cross-sectional shape. Side surfaces of the third and fourth slits U4″ and U4″ may be substantially perpendicular to each other in a cross-section in the first and third directions, but an embodiment thereof is not limited thereto, and the side surfaces may have a substantially hourglass cross-sectional shape. The regions including the metal material M of each of the plurality of first conductive electrodes 121a″, the plurality of second conductive electrodes 122a″, the first conductive connection portion 121b″ and the second conductive connection portion 122b″ may include a titanium layer and a copper layer formed by sputtering, that is, sputtered titanium and sputtered copper as seed layers, and may include electrolytic copper formed by electrolytic plating based on the copper as a plating layer. If desired, chemical copper formed by electroless plating may be further included as a seed layer, or only chemical copper formed by electroless plating may be included as a seed layer.

Other descriptions may be substantially the same as in the embodiment of the glass substrate structure 100A according to an example and the glass substrate structure 100B according to another example.

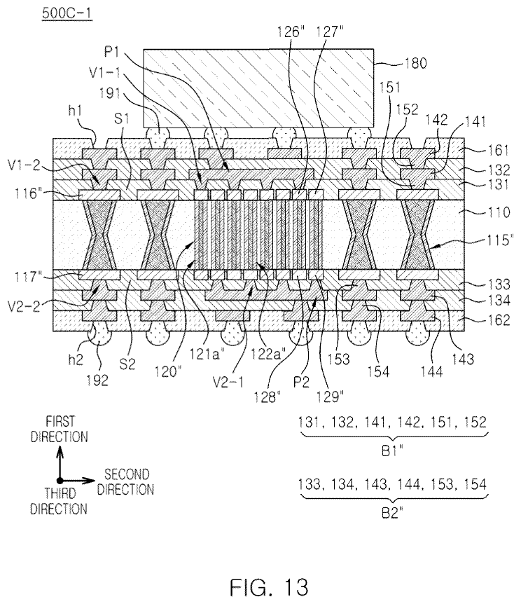

FIG. 13 is a cross-sectional diagram illustrating a modified example of the glass substrate structure illustrated in FIG. 11.

Referring to the drawings, a glass substrate structure 500C-1 according to the modified example may have a multilayer substrate structure including the glass substrate structure 100C according to the other example described above as a core layer. For example, the glass substrate structure 500C-1 according to the modified example may include a glass layer 110 including a plurality of conductive through-vias 115 and capacitor members 120″ formed thereon, a first built-up layer B1″ disposed on a first surface S1 of the glass layer 110, a second built-up layer B2″ disposed on a second surface S2 of the glass layer 110, a first solder resist layer 161 disposed on the first built-up layer B1″, and a second solder resist layer 162 disposed on the second built-up layer B2″. For example, the glass substrate structure 500C-1 according to the modified example may have a package substrate structure. Accordingly, the structure may be easily applied to a product requiring a large-area substrate.

The first built-up layer B1″ may include a plurality of first built-up insulating layers 131 and 132, a plurality of first built-up wiring layers 141 and 142 disposed on or in the first built-up insulating layers 131 and 132, respectively, and a plurality of first built-up via layers 151 and 152 disposed in the first built-up insulating layers 131 and 132, respectively. Accordingly, various wiring designs and electrical connection paths may be provided in the first built-up layer B1″. Also, the second built-up layer B2″ may include a plurality of second built-up insulating layers 133 and 134, a plurality of first built-up wiring layers 143 and 144 disposed on or in the second built-up insulating layers 133 and 134, respectively, and a plurality of first built-up via layers 153 and 154 disposed in the first built-up insulating layers 133 and 134, respectively. Accordingly, the second built-up layer B2″ may also provide a variety of wiring designs and electrical connection paths. The number of the plurality of first built-up insulating layers 131 and 132, the plurality of second built-up insulating layers 133 and 134, the plurality of first built-up wiring layers 141 and 142, the plurality of second built-up wiring layers 143 and 144, the plurality of first built-up via layers 151 and 152 and the plurality of second built-up via layers 153 and 153 may be greater than the illustrated example, but an embodiment thereof is not limited thereto, and the number of layer may be one.

A plurality of first conductive pads 116″ each covering one side of each of the plurality of conductive through-vias 115″, a plurality of first conductive cover electrodes 126″ covering one side of each of the plurality of first conductive electrodes 121a″ and the first conductive connection portion 121b″, and a plurality of second conductive cover electrodes 127″ covering one side of each of the second conductive electrodes 122a″ and the second conductive connection portion 122b″ may be disposed on the first surface S1 of the glass layer 110. Also, a plurality of second conductive pads 117″ each covering the other side of each of the conductive through-vias 115″, a plurality of third conductive cover electrodes 128″ covering the other side of the first conductive electrodes 121a″ and the first conductive connection portion 121b″, and a plurality of fourth conductive cover electrodes 129″ covering the other side of the second conductive electrodes 122a″ and the second conductive connection portion 122b″ may be disposed on the second surface S2 of the glass layer 110. For example, the dielectric material D may not be exposed to one side and the other side through the plurality of first and second conductive pads 116″ and 117″ and first to fourth conductive cover electrodes 126″, 127″, 128″, and 129″ disposed on the first surface S1 and second surface S2 of the glass layer 110. However, an embodiment thereof is not limited thereto, and if desired, the first and second conductive pads 116″ and 117″ and the first to fourth conductive cover electrodes 126″, 127″, 128″, and 129″ may not be provided. In this case, a size of the metal material M may be adjusted to be connected to built-up connection vias V1-1, V1-2, V2-1, and V2-2, and/or sizes of the built-up connections via V1-1, V1-2, V2-1, and V2-2 may be adjusted to be connected to the metal material M.

One 151 of a plurality of first built-up via layers 151 and 152 may include a plurality of 1-1 built-up connection vias V1-1 electrically connecting at least a portion of one 141 of the plurality of first built-up wiring layers 141 and 142, for example, a first conductive pattern P1, to a plurality of first conductive electrodes 121a″ and a first conductive connection portion 121b″. Each of the plurality of 1-1 built-up connection vias V1-1 may be connected to the first conductive cover electrode 126″. Accordingly, a path may be provided in the first built-up layer B1″ electrically connected to the capacitor member 120″. Also, the plurality of second built-up via layers 153 and 154 may include at least a portion of a plurality of second built-up wiring layers 143 and 144, a plurality of 2-1 built-up connections via V2-1 electrically connecting the second conductive pattern P2 to the plurality of second conductive electrodes 122a″ and the second conductive connection portion 122b″. Each of the plurality of 2-1 built-up connections via V2-1 may be connected to the fourth conductive cover electrode 129″. Accordingly, a path may also be provided in the second built-up layer B2″ electrically connected to the capacitor member 120″.

The first and second conductive patterns P1 and P2 may be electrically connected to the power rail and ground, respectively, in the first and second built-up layers B1″ and B2″, but an embodiment thereof is not limited thereto, and both the patterns may be electrically connected to a signal line in the first and second built-up layers B1″ and B2″, or may be electrically connected to a signal line and ground, respectively, in the first and second built-up layers B1″ and B2″. For example, the patterns may be connected in various forms depending on a function and role of the capacitor member 120″. If desired, the first and second conductive patterns P1 and P2 may be disposed substantially at the same level, and may be included, for example, in one of the first built-up wiring layer 141 or one of the second built-up wiring layer 143, respectively. In this case, the plurality of 1-1 built-up connection vias V1-1 and the plurality of 2-1 built-up connection vias V2-1 may also be disposed at substantially the same level, for example, the vias may be included in one of the first built-up via layer 151 or one of the second built-up via layer 153. For example, various designs may be configured.

One 151 of the plurality of first built-up via layers 151 and 152 may further include a plurality of 1-2 built-up connection vias V1-2 electrically connecting at least the other portion of one of the plurality of first built-up wiring layers 141 and 142 to one side of each of the plurality of conductive through-vias 115″. For example, each of the plurality of 1-2 built-up connection vias V1-2 may be connected to the plurality of first conductive pads 116″. Also, the plurality of second built-up via layers 153 and 154 may further include a plurality of 2-2 built-up connections vias V2-2 electrically connecting at least a portion of one of the plurality of second built-up wiring layers 143 and 144 to the other side of each of the plurality of conductive through-vias 115″. For example, the plurality of 2-2 built-up connections vias V2-2 may be connected to the plurality of second conductive pads 117″, respectively. Accordingly, an electrical connection path between the first built-up layer B1″and the second built-up layer B2″may be provided.

Hereinafter, components of the glass substrate structure 500C-1 according to the modified example will be described in greater detail with reference to the drawings.

Each of the plurality of first and second conductive pads 116″ and 117″ may include a metal. The metal may include copper (Cu), aluminum (Al), silver (Ag), tin (Sn), gold (Au), nickel (Ni), lead (Pb), titanium (Ti), and/or alloys thereof. For example, the plurality of first and second conductive pads 116″ and 117″ may include a titanium layer and a copper layer formed by sputtering, that is, sputtered titanium and sputtered copper, as seed layers, and may include electrolytic copper formed by electrolytic plating based on the titanium layer and the sputtered copper as a plating layer. If desired, chemical copper formed by electroless plating may further be included as a seed layer, or only chemical copper formed by electroless plating may be included as a seed layer. The plurality of first and second conductive pads 116″ and 117″ may perform various functions depending on a design. For example, the plurality of first and second conductive pads 116″ and 117″ may be pads for signal transmission, pads for power transmission, or pads for ground transmission, respectively.

Each of the first to fourth conductive cover electrodes 126″, 127″, 128″, and 129″ may include a metal. The metal may include copper (Cu), aluminum (Al), silver (Ag), tin (Sn), gold (Au), nickel (Ni), lead (Pb), titanium (Ti), and/or alloys thereof. For example, each of the first to fourth conductive cover electrodes 126″, 127″, 128″, and 129″ may include a titanium layer and a copper layer formed by sputtering, that is, sputtered titanium and sputtered copper, as seed layers, and electrolytic copper formed by electrolytic plating based on the titanium layer and the copper layer formed by electroless plating may be included as a plating layer. If desired, chemical copper formed by electroless plating may be further included as a seed layer, and only chemical copper formed by electroless plating may be included as a seed layer. The first to fourth conductive cover electrodes 126″, 127″, 128″, and 129″ may perform various functions depending on a design. For example, the first to fourth conductive cover electrodes 126″, 127″, 128″, and 129″ may be a cover electrode for signal connection, a cover electrode for power transmission, or a cover electrode for ground transmission, respectively.

Other descriptions may be substantially the same as in the embodiment of the glass substrate structure 100A according to an example and the glass substrate structure 500A-1 according to a modified example thereof, the glass substrate structure 100B according to another example and the glass substrate structure 500B-1 according to a modified example thereof, and the glass substrate structure 100C according to another example.

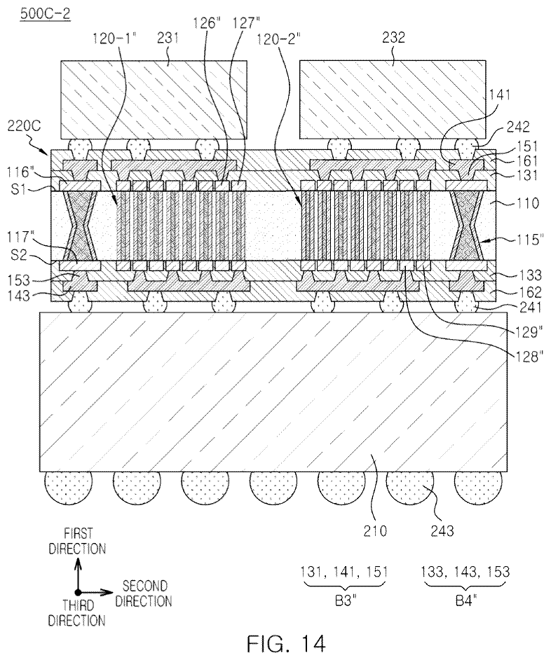

FIG. 14 is a cross-sectional diagram illustrating a modified example of the glass substrate structure illustrated in FIG. 11.

Referring to the drawings, the glass substrate structure 500C-2 according to the modified example may have an assembly structure of the package substrate 210 and the interposer 220C, and the interposer 220C may include the glass substrate structure 100C according to the other example described above. For example, the glass substrate structure 500C-2 according to the modified example may include the package substrate 210 and the interposer 220C mounted on the package substrate 210, and the interposer 220C may include a glass layer 110 on which a plurality of conductive through-vias 115 and a plurality of capacitor members 120-1″ and 120-2″ are formed. Each of the plurality of capacitor members 120-1″ and 120-2″ may have substantially the same structure as that of the capacitor member 120″ described above. The glass substrate structure 500C-2 according to the modified example may have an assembly structure as above, and the structure may thus be easily applied to various products requiring a package substrate and/or an interposer.

The interposer 220C may further include third and fourth built-up layers B3″ and B4″ disposed on the first surface S1 and the second surface S2 of the glass layer 110, respectively, and first and second solder resist layers 161 and 162 disposed on the third and fourth built-up layers B3″ and B4″, respectively. The third built-up layer B3″ may include one or more first built-up insulating layers 131, one or more first built-up wiring layers 141, and one or more first built-up via layers 151. The fourth built-up layer B4″ may include one or more second built-up wiring layers 133, one or more second built-up wiring layers 143, and one or more second built-up via layers 153. Each of the first and second built-up wiring layers 141 and 143 may include a plurality of conductive patterns electrically connected to the plurality of capacitor members 120-1″ and 120-2″, respectively, and each of the first and second built-up via layers 151 and 153 may include a plurality of built-up connection vias providing such electrical connection paths, and also, the first and second built-up via layers 151 and 153 may further include a plurality of built-up connection vias electrically connected to the plurality of conductive through-vias 115, respectively. The specific descriptions thereof may be substantially the same as in the embodiment of the glass substrate structure 500C-1 described above.

If desired, the third built-up layer B3″ and/or the fourth built-up layer B4″ may not be provided. For example, a plurality of first electrical connection metals 241 and/or a plurality of second electrical connection metals 242 may be directly connected to the first conductive pad 116″, the second conductive pad 117″, the first conductive cover electrode 126″, the second conductive cover electrode 127″, the third conductive cover electrode 128″, and/or the fourth conductive cover electrode 129″. Alternatively, additional wiring of various types may be formed on the first surface S1 and/or the second surface S2 of the glass layer 110. For example, the structure of the interposer 220C may be varied.

If desired, a plurality of capacitor members 120-1″ and 120-2″ may be electrically connected only to a plurality of conductive patterns included in the third built-up layer B3″, or only to a plurality of conductive patterns included in the fourth built-up layer B4″. Also, a plurality of conductive patterns included in the third built-up layer B3″ and/or the fourth built-up layer B4″ may be electrically connected to a power rail and ground, or both may be electrically connected to a signal line, or may be electrically connected to a signal line and ground. For example, as described above in relation to the glass substrate structure 500C-1 above, various designs may be configured, and may also have various connection forms depending on functions and roles of the plurality of capacitor members 120-1″and 120-2″.

Other descriptions may be substantially the same as in the embodiment of the glass substrate structure 100A according to an example and the glass substrate structures 500A-1 and 500A-2 according to the modified example thereof, the glass substrate structure 100B according to another example and the glass substrate structures 500B-1 and 500B-2 according to the modified example thereof, and the glass substrate structure 100C according to another example and the glass substrate structure 500C-1 according to the modified example thereof.

According to the aforementioned embodiments, a glass substrate structure in which capacitors of various capacitances may be performed without a capacitor embedding process may be provided.

Also, a glass substrate structure which may improve signal integrity and power integrity performance may be provided.

In embodiments, a glass substrate structure may refer to various forms of substrate structures including a glass layer. For example, a glass substrate in which other components such as through-vias or capacitor members may be formed on a glass layer, a printed circuit board of various forms and structures including such a glass substrate as a core layer and/or a built-up layer, and a package structure or assembly structure including such a printed circuit board may be included in the glass substrate structure.

In the present disclosure, the term “covering” may include covering entirely and also covering at least a portion, and may also include covering directly and also covering indirectly. Also, the term “filling” may include filling completely and also filling roughly, and may include, for example, the presence of some gaps or voids.

In the present disclosure, process errors, positional deviations, and measurement errors occurring in the manufacturing process may be included. For example, the notion that the line width, distance, thickness, and height are substantially the same may include case in which the elements are completely the same in numerical sense, and also case in which the elements may have similar values. Also, the notion of “having substantially a predetermined shape” may include case of having almost the same shape and also having a similar shape.

In the present disclosure, “on the cross-section” may indicate the cross-sectional shape when the object is cut vertically, or the cross-sectional shape when the object is viewed from the side. Also, “on a plane” may indicate a plane shape when the object is cut horizontally, or a plane shape when the object is viewed from a top-view or bottom-view.

The terms “lower side,” “lower portion,” “lower surface,” and the like, may be used to refer to a surface formed in a downward direction with reference to a cross-section in the diagrams for ease of description, the terms “upper side,” “upper portion,” “upper surfaces,” and the like, may be used to refer to a surface formed in an upward direction, and the terms “side portion,” “side surface,” and the like, may be used to refer to a surface formed taken in the direction perpendicular to a upper surface and lower surface. The terms, however, may be defined as above for ease of description, and the scope of right of the embodiments is not particularly limited to the above terms.

In the embodiments, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” Further, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the embodiments.

A thickness, width, length, depth, line width, distance, pitch, and the like, may be measured using a scanning microscope or optical microscope based on a cross section of a printed circuit board which may be polished or cut. The cross-section may be a vertical cross-section or a horizontal cross-section, and each value may be measured based on the required cross-section. For example, a width of an upper end and/or lower end of a via may be measured on a cross-section cut along a central axis of the via. In this case, when the value is not constant, the value may be determined as an average value of the values measured at five random points. A minimum value may be determined as the smallest value measured on the corresponding layer or region.

In the embodiments, the term “embodiment” may not refer to one same embodiment, and may be provided to describe and emphasize different unique features of each embodiment. The above suggested embodiments may be implemented do not exclude the possibilities of combination with features of other embodiments. For example, even though the features described in one embodiment are not described in the other embodiment, the description may be understood as relevant to the other embodiment unless otherwise indicated.

An expression used in the singular encompasses the expression of the plural, unless it has a clearly different meaning in the context.

While the embodiments have been illustrated and described above, it will be apparent to those skilled in the art that modifications and variations could be made without departing from the scope of the present disclosure as defined by the appended claims.

What is claimed is:

1. A glass substrate structure, comprising:
a glass layer having a first surface and a second surface opposing each other in a first direction;
a plurality of conductive through-vias penetrating at least a portion of the glass layer between the first surface and the second surface; and
a capacitor member including a plurality of conductive electrodes each penetrating at least a portion of the glass layer between the first surface and the second surface,
wherein at least a portion of the plurality of conductive electrodes has regions overlapping each other in a second direction perpendicular to the first direction.

2. The glass substrate structure of claim 1, wherein the plurality of conductive electrodes include a plurality of first conductive electrodes and a plurality of second conductive electrodes disposed alternately and spaced apart from each other in the second direction.

3. The glass substrate structure of claim 2,
wherein the plurality of first conductive electrodes are connected to each other in parallel, and
wherein the plurality of second conductive electrodes are connected to each other in parallel.

4. The glass substrate structure of claim 2, wherein at least a portion of the glass layer is disposed between the plurality of first conductive electrodes and the plurality of second conductive electrodes.

5. The glass substrate structure of claim 2, wherein the plurality of first conductive electrodes and the plurality of second conductive electrodes have regions overlapping each other in the second direction.

6. The glass substrate structure of claim 2, wherein each of the plurality of first and second conductive electrodes has a substantially panel shape in which each of a length in the first direction and a length in a third direction perpendicular to the first and second directions is longer than a length in the second direction.

7. The glass substrate structure of claim 6,
wherein the capacitor member further includes first and second conductive connection portions each penetrating at least a portion between the first surface and the second surface of the glass layer,
wherein the first and second conductive connection portions are spaced apart from each other in the third direction,
wherein the plurality of first and second conductive electrodes are disposed between the first and second conductive connection portions,
wherein each of the plurality of first conductive electrodes is connected to the first conductive connection portion, and
wherein each of the plurality of second conductive electrodes is connected to the second conductive connection portion.

8. The glass substrate structure of claim 7, wherein each of the first and second conductive connection portions has a substantially panel shape in which lengths in the first and second directions is longer than a length in the third direction.

9. The glass substrate structure of claim 8, wherein each of the plurality of first and second conductive electrodes and the first and second conductive connection portions includes a metal material.

10. The glass substrate structure of claim 9,
wherein a dielectric material is disposed in each of the plurality of first and second conductive electrodes, and
wherein the metal material surrounds at least a portion of the dielectric material in a cross-section in the second and third directions in each of the plurality of first and second conductive electrodes.

11. The glass substrate structure of claim 10, further comprising:
a first conductive cover electrode disposed on the first surface of the glass layer and covering one side of each of the plurality of first conductive electrodes and the first conductive connection portion;
a second conductive cover electrode disposed on the first surface of the glass layer and covering one side of each of the plurality of second conductive electrodes and the second conductive connection portion;
a third conductive cover electrode disposed on the second surface of the glass layer and covering the other side of each of the plurality of first conductive electrodes and the first conductive connection portion; and
a fourth conductive cover electrode disposed on the second surface of the glass layer and covering the other side of each of the plurality of second conductive electrodes and the second conductive connection portion.

12. The glass substrate structure of claim 7, further comprising:
a first insulating layer disposed on the first surface of the glass layer;
a first conductive pattern disposed on the first insulating layer;
a second insulating layer disposed on the second surface of the glass layer;
a second conductive pattern disposed on the second insulating layer;
one or more first conductive connection vias each penetrating at least a portion of the first insulating layer and connecting the plurality of first conductive electrodes and the first conductive connection portion to the first conductive pattern; and
one or more second conductive connection vias each penetrating at least a portion of the second insulating layer and connecting the plurality of second conductive electrodes and the second conductive connection portion to the second conductive pattern.

13. The glass substrate structure of claim 2,
wherein each of the plurality of first conductive electrodes includes a plurality of first conductive vias spaced apart from each other in a third direction perpendicular to the first and second directions, and
wherein each of the plurality of second conductive electrodes includes a plurality of second conductive vias spaced apart from each other in the third direction.

14. The glass substrate structure of claim 13, wherein each of the plurality of first conductive vias of each of the plurality of first conductive electrodes and each of the plurality of second conductive vias of each of the plurality of second conductive electrodes has a substantially circular or elliptical shape in a cross-section in the second and third directions.

15. The glass substrate structure of claim 13, further comprising:
a first insulating layer disposed on the first surface of the glass layer;
a first conductive pattern disposed on the first insulating layer;
a second insulating layer disposed on the second surface of the glass layer;
a second conductive pattern disposed on the second insulating layer;
a plurality of first conductive connection vias each penetrating at least a portion of the first insulating layer and connecting each of the plurality of first conductive vias of each of the plurality of first conductive electrodes to the first conductive pattern; and
a plurality of second conductive connection vias each penetrating at least a portion of the second insulating layer and connecting each of the plurality of second conductive vias of each of the plurality of second conductive electrodes to the second conductive pattern.

16. The glass substrate structure of claim 1, further comprising:
a first built-up layer disposed on the first surface of the glass layer; and
a second built-up layer disposed on the second surface of the glass layer,
wherein the first built-up layer includes one or more first built-up insulating layers, one or more first built-up wiring layers, and one or more first built-up via layers, and
wherein the second built-up layer includes one or more second built-up insulating layers, one or more second built-up wiring layers, and one or more second built-up via layers.

17. The glass substrate structure of claim 16,
wherein one of the one or more first built-up via layers includes one or more 1-1 built-up connection vias connecting a portion of the plurality of conductive electrodes to at least a portion of one of the one or more first built-up wiring layers, and
wherein one of the one or more second built-up via layers includes one or more 2-1 built-up connection vias connecting the other portion of the plurality of conductive electrodes to at least a portion of one of the one or more second built-up wiring layers.

18. The glass substrate structure of claim 17,
wherein one of the one or more first built-up via layers further includes a plurality of 1-2 built-up connection vias connecting at least a portion of one of the one or more first built-up wiring layers to one side of each of the plurality of conductive through-vias, and wherein one of the one or more second built-up via layers further includes a plurality of 2-2 built-up connection vias connecting at least a portion of one of the one or more second built-up wiring layers to the other side of each of the plurality of conductive through-vias.

19. The glass substrate structure of claim 16, further comprising:
a first solder resist layer disposed on the first built-up layer; and
a second solder resist layer disposed on the second built-up layer,
wherein the first solder resist layer has a plurality of first openings,
wherein the plurality of first openings each exposing at least a portion of the first built-up wiring layer disposed on an outermost side of the one or more first built-up wiring layers,
wherein the second solder resist layer has a plurality of second openings, and
wherein the plurality of second openings each exposing at least a portion of the second built-up wiring layer disposed on an outermost side of the one or more second built-up wiring layers.

20. The glass substrate structure of claim 19, further comprising:
a plurality of first electrical connection metals disposed in the plurality of first openings and connected to at least a portion of an exposed portion of the first built-up wiring layer disposed on the outermost side of the one or more first built-up wiring layers;
a plurality of second electrical connection metals disposed in the plurality of second openings and connected to at least a portion of an exposed portion of the second built-up wiring layer disposed on the outermost side of the one or more second built-up wiring layers; and
an electronic component connected to the plurality of first electrical connection metals and mounted on the first solder resist layer through the plurality of first electrical connection metals,
wherein the electronic component includes a system-on-chip.

21. The glass substrate structure of claim 1, further comprising:
a package substrate disposed on the second surface of the glass layer; and
a plurality of first electrical connection metals disposed between the glass layer and the package substrate,
wherein one or more of the conductive through-via and the capacitor member is connected to the package substrate through the plurality of first electrical connection metals.

22. The glass substrate structure of claim 21, further comprising:
a plurality of electronic components each disposed on the first surface of the glass layer; and
a plurality of second electrical connection metals each disposed between the glass layer and the plurality of electronic components,
wherein one or more of the conductive through-via and the capacitor member is connected to the plurality of electronic components through the plurality of second electrical connection metal, and
wherein each of the plurality of electronic components include a system-on-chip.

23. A glass substrate structure, comprising:
a glass layer;
a plurality of first and second slits each penetrating the glass layer in a first direction, spaced apart from each other in a second direction perpendicular to the first direction, and each extending to a predetermined length in a third direction perpendicular to the first and second directions; and
a metal material disposed in at least a portion of each of the plurality of first and second slits.

24. The glass substrate structure of claim 23, wherein the plurality of first slits and the plurality of second slits are spaced apart from each other in the second direction and are disposed alternately, and have regions overlapping each other in the second direction.

25. The glass substrate structure of claim 23, further comprising:
third and fourth slits each penetrating the glass layer in the first direction, each extending to a predetermined length in the second direction, and spaced apart from each other in the third direction,
wherein the metal material further is disposed in at least a portion of each of the third and fourth slits,
wherein the plurality of first and second slits are disposed between the third and fourth slits,
wherein each of the plurality of first slits is connected to the third slit, and
wherein each of the plurality of second slits is connected to the fourth slit.

26. The glass substrate structure of claim 25,
wherein lengths in the first and third directions of each of the plurality of first and second slits are longer than a length in the second direction, and
wherein lengths in the first and third directions of the third and fourth slits are longer than a length in the third direction.

27. The glass substrate structure of claim 25, further comprising:
a capacitor member having at least a portion disposed in the glass layer,
wherein the capacitor member includes the plurality of first and second slits, the third and fourth slits and the metal material.

28. The glass substrate structure of claim 27, further comprising:
a first insulating layer disposed on one side of the glass layer;
a second insulating layer disposed on the other side of the glass layer;
a first conductive pattern disposed on the first insulating layer;
a second conductive pattern disposed on the second insulating layer;
a first conductive connection via penetrating at least a portion of the first insulating layer and connecting the metal material disposed in each of the plurality of first slits and the third slit to the first conductive pattern; and
a second conductive connection via penetrating at least a portion of the second insulating layer and connecting the metal material disposed in each of the plurality of second slits and the fourth slit to the second conductive pattern.

29. The glass substrate structure of claim 25, further comprising:
a plurality of dielectric materials disposed in at least a portion of each of the first and second slits,
wherein the metal material is substantially conformally disposed on a wall surface of each of the plurality of first and second slits, and
wherein the dielectric material is disposed in at least a portion between metal materials of the plurality of first and second slits.

30. The glass substrate structure of claim 29,
wherein the metal material is entirely disposed in each of the third and fourth slits.

31. A glass substrate structure, comprising:
a glass layer having a first surface and a second surface opposing each other in a first direction;
a capacitor member including first conductive electrodes and second conductive electrodes penetrating through the glass layer from the first surface to the second surface, and alternately disposed in a second direction crossing the first direction;
a first conductive pattern disposed on the glass layer and connected to the first conductive electrodes; and
a second conductive pattern disposed on the glass layer and connected to the second conductive electrodes.

32. The glass substrate structure of claim 31, wherein the first conductive electrodes and the second conductive electrodes at least partially overlap each other in the second direction.

33. The glass substrate structure of claim 31,
wherein the capacitor member further includes first and second conductive connection portions penetrating through the glass layer from the first surface to the second surface,
wherein the first and second conductive connection portions are spaced apart from each other in the third direction,
wherein the first and second conductive electrodes are disposed between the first and second conductive connection portions,
wherein the plurality of first conductive electrodes are connected to the first conductive connection portion, and
wherein the second conductive electrodes are connected to the second conductive connection portion.

34. The glass substrate structure of claim 31, further comprising:
a first insulating layer disposed on the first surface of the glass layer;
a second insulating layer disposed on the second surface of the glass layer;
one or more first conductive connection vias each penetrating at least a portion of the first insulating layer and connected between the first conductive electrodes and the first conductive pattern; and
one or more second conductive connection vias each penetrating at least a portion of the second insulating layer and connected between the second conductive electrodes and the second conductive pattern.

35. The glass substrate structure of claim 31,
wherein each of the first conductive electrodes includes a plurality of first conductive vias spaced apart from each other in a third direction crossing the first and second directions, and
wherein each of the second conductive electrodes includes a plurality of second conductive vias spaced apart from each other in the third direction.
